(19) United States
(12) Patent Application Publication
(10) Pub. No.: US 2017/0294398 A1
(43) Pub. Date: Oct. 12, 2017

(54) SEMICONDUCTOR DEVICE THAT INCLUDES A MOLECULAR BONDING LAYER FOR BONDING OF ELEMENTS

(71) Applicant: KABUSHIKI KAISHA TOSHIBA, Tokyo (JP)

(72) Inventor: Akihiko HAPPOYA, Ome Tokyo (JP)

(21) Appl. No.: 15/441,013

(22) Filed: Feb. 23, 2017

Related U.S. Application Data
(60) Provisional application No. 62/324,686, filed on Apr. 19, 2016.
(60) Provisional application No. 62/319,450, filed on Apr. 7, 2016.
(60) Provisional application No. 62/382,048, filed on Aug. 31, 2016.

(51) Int. Cl. H01L 23/00; H01L 23/498; H01L 23/31

(52) U.S. Cl. CPC H01L 24/32; H01L 23/3157; H01L 23/49827; H01L 23/49816; H01L 2224/32501; H01L 2224/32104

(57) ABSTRACT

A semiconductor device includes a semiconductor chip covered with a resin layer, the semiconductor chip including an electrode pad at a surface of the semiconductor chip, a first insulating layer covering the surface of the semiconductor chip and having a via hole at a region corresponding to the electrode pad, a conductive layer extending along a surface of the electrode pad, a side surface of the via hole, and a planar surface the first insulating layer, to a region beyond a planar region defined by the semiconductor chip, a second insulating layer on the first insulating layer and covering the conductive layer; and a molecular bonding layer formed between the first insulating layer and the second insulating layer and including a molecular portion covalently bonded to a material of the conductive layer and a material of the second insulating layer.

### CROSS-REFERENCE TO RELATED APPLICATIONS

This application is based upon and claims the benefit of priority from U.S. Provisional Patent Application No. 62/319,450, filed on Apr. 7, 2016, U.S. Provisional Patent Application No. 62/324,686, filed on Apr. 19, 2016, and U.S. Provisional Patent Application No. 62/382,048, filed on Aug. 31, 2016, the entire contents of all of which are incorporated herein by reference.

### FIELD

Embodiments described herein relate generally to a semiconductor device and a method of manufacturing the semiconductor device.

### BACKGROUND

Semiconductor devices including a conductor, an insulating layer, and a metal plating layer are known.

### BRIEF DESCRIPTION OF THE DRAWINGS

FIG. 1 is a perspective view of an electronic device according to a first embodiment.

FIG. 2 is a cross-sectional view of a semiconductor device according to the first embodiment.

FIG. 3 schematically illustrates a composition of a molecular bonding layer in the semiconductor device according to the first embodiment.

FIGS. 4A and 4B are cross-sectional views of a structure in process to show a flow of a method of manufacturing the semiconductor device according to the first embodiment.

FIG. 5 is a cross-sectional view of a part of a semiconductor device according to a modified example of the first embodiment.

FIG. 6 is a cross-sectional view of a semiconductor device according to a second embodiment.

FIG. 7 is an enlarged cross-sectional view of a vicinity of a third molecular bonding layer in the semiconductor package according to the second embodiment.

FIGS. 8A-8J are cross-sectional views of a structure in process to show a process of a method of manufacturing the semiconductor device according to the second embodiment.

FIG. 9 is a cross-sectional view of a semiconductor device according to a fourth embodiment.

FIG. 10A-10G are cross-sectional views of a structure in process to show a process of a method of manufacturing the semiconductor device according to the fourth embodiment.

### DETAILED DESCRIPTION

A semiconductor device includes a semiconductor chip covered with a resin layer, the semiconductor chip including an electrode pad at a surface of the semiconductor chip, a first insulating layer covering the surface of the semiconductor chip and having a via hole at a region corresponding to the electrode pad, a conductive layer (e.g., a wiring) extending along a surface of the electrode pad, a side surface of the via hole, and a surface the first insulating layer, to a region beyond (outside of) a planar region defined by the semiconductor chip, a second insulating layer on the first insulating layer and covering the conductive layer; and a molecular bonding layer between the first insulating layer and the second insulating layer and including a molecular portion covalently bonded to a material of the conductive layer and a material of the second insulating layer.

A semiconductor device and a method of manufacturing a semiconductor device according to embodiments will be described below with reference to the drawings. In the following description, components having the same or similar functions are denoted by the same reference numerals and redundant descriptions thereof will be omitted. The drawings are schematic and the numbers, thicknesses, widths, proportions, and the like of components may be different from those of actual components.

### First Embodiment

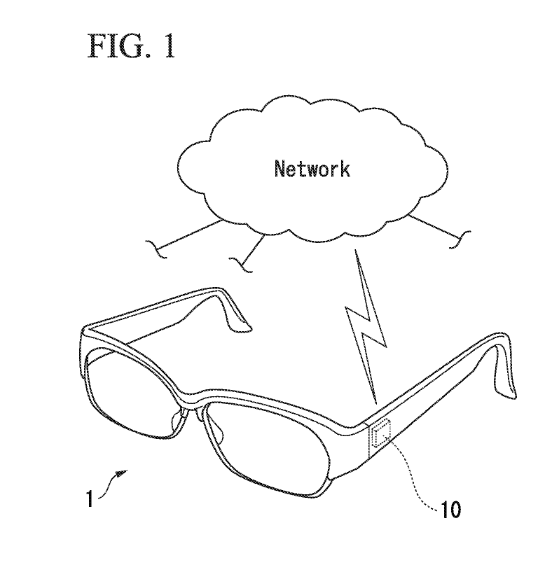

A first embodiment will be described with reference to FIG. 1 to FIG. 4B.

FIG. 1 is a perspective view of an electronic device 1 according to the first embodiment. The electronic device 1 includes a semiconductor package (device) 10 according to the first embodiment. The electronic device 1 is, for example, a wearable device, but is not limited thereto. The electronic device 1 is an electronic device conforming to, for example, Internet of Things (IoT), and can be connected to the Internet through wireless or wired networks. In this case, an example of the semiconductor package 10 includes a processor (e.g., a central processing unit), a sensor, and a wireless module. However, the electronic device 1 and the semiconductor package 10 are not limited to the above example. The electronic device 1 may be an electronic device for a vehicle or electronic devices for other purposes. The semiconductor package 10 may be a semiconductor component that is used as a vehicle component or a power semiconductor, or may be a semiconductor component used for other purposes. In addition, the semiconductor package 10 according to second to fourth embodiments to be described below may be included in the electronic device 1.

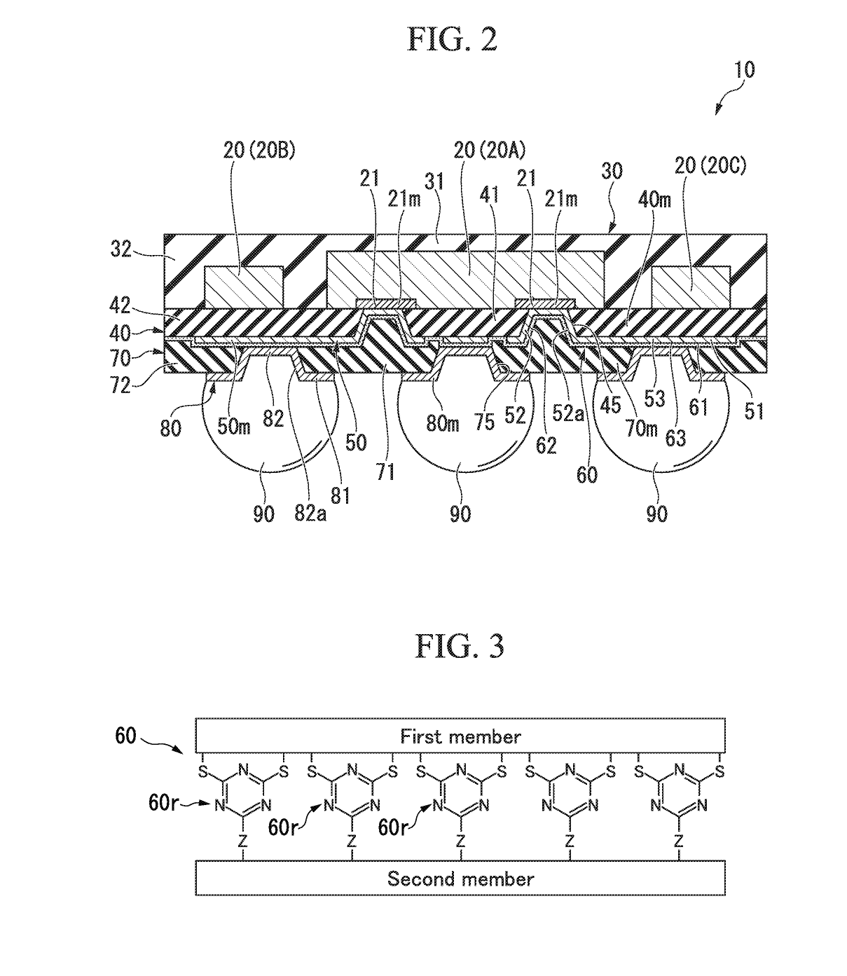

FIG. 2 is a cross-sectional view showing the semiconductor package 10 of the first embodiment.

The semiconductor package 10 according to the present embodiment is, for example, a Fan Out Wafer Level Package (FOWLP). As will be described below in detail, the semiconductor package 10 includes a semiconductor chip 20 and a redistribution layer (RDL) 50 that is larger than the semiconductor chip 20. Here, the “redistribution layer” herein refers to a conductive layer connected to a terminal (electrode) of an integrated circuit (chip) and that is disposed at or extends to the outside of a planar region defined by integrated circuit. In the present embodiment, the “redistribution layer” refers to a layer that is electrically connected to a first terminal (e.g., solder connector 90) and disposed outside a planar region defined by the semiconductor chip 20 and a layer that is electrically connected to a second terminal (e.g., conductive pad 21) of the semiconductor chip 20 and extends to the outside of a planar region defined by the semiconductor chip 20. The semiconductor package 10 is not limited to an FOWLP, and may be a Wafer Level Chip Size Package (WLCSP) or other types of semiconductor package. The semiconductor package 10 is an example of a “semiconductor device.”

As shown in FIG. 2, the semiconductor package 10 includes, for example, a first semiconductor chip 20A, a second semiconductor chip 20B, a third semiconductor chip 20C, a resin mold 30, a lower insulating layer 40, a first redistribution layer 50, a molecular bonding layer 60, an upper insulating layer 70, a second redistribution layer 80, and solder connectors 90. In the present disclosure, “upper” and “lower” are determined based on a process of producing the semiconductor package 10. However, modifiers such as “upper” and “lower” are provided for convenience of description, and positions, functions, and configurations of the insulating layers 40 and 70 are not limited thereby.

The first semiconductor chip 20A, the second semiconductor chip 20B, and the third semiconductor chip 20C are members including, for example, a silicon-containing semiconductor, as a constituent material, and, for example, a bare chip. An example of each of the first to third semiconductor chips 20A, 20B, and 20C may be referred to as a “silicon chip.” The first to third semiconductor chips 20A, 20B, and 20C are, for example, heterojunction field effect transistors (HFETs) made of a material such as GaN or SiC, or lateral double diffuse OS transistors (LDMOSs) made of a material such as Si. In addition, other examples of the semiconductor chips 20A, 20B, and 20C, include an optical semiconductor element, a piezoelectric element, a memory element, a microcomputer element, a sensor element, and a wireless communication element. The “semiconductor chip” referred to herein may be a component including an electric circuit and is not limited to a semiconductor chip for a specific purpose.

For example, the first semiconductor chip 20A is a processor (e.g., a central processing unit). For example, the second semiconductor chip 20B is a sensor configured to detect at least one of acceleration, inclination, geomagnetism, temperature, vibration or other physical quantities. For example, the third semiconductor chip 20C is a wireless communication module. By controlling the second semiconductor chip 20B and the third semiconductor chip 20C, the first semiconductor chip 20A wirelessly transmits a detection result detected by the second semiconductor chip 20B outside of the semiconductor chip 20 via the third semiconductor chip 20C. Also, functions of the first to third semiconductor chips 20A, 20B, and 20C are not limited to the above example. In addition, the semiconductor package 10 is not limited to a semiconductor package including a plurality of semiconductor chips, but includes at least one semiconductor chip. In the following description, when the first to third semiconductor chips 20A, 20B, and 20C are not particularly distinguished, they will be referred to as the “semiconductor chip 20.”

As shown in FIG. 2, the semiconductor chip 20 includes a plurality of conductive pads (i.e., connection portions, or electrical connection portions) 21. The conductive pad 21 is an example each of a “second terminal” and a “conductor.” The plurality of conductive pads 21 is exposed on an outer surface of the semiconductor chip 20. Although not shown in FIG. 2, the second and third semiconductor chips 20B and 20C also include a plurality of conductive pads 21 similarly to the first semiconductor chip 20A. The conductive pad 21 is made of a metal (i.e., a metal material) 21m. The metal 21m is, for example, copper, a copper alloy, aluminum, or an aluminum alloy (e.g., an aluminum-silicon based alloy), but not limited thereto.

The resin mold (i.e., an insulating portion) 30 covers the first to third semiconductor chips 20A, 20B, and 20C. The resin mold 30 integrally seals the first to third semiconductor chips 20A, 20B, and 20C. The resin mold 30 includes a first portion (i.e., a first region) 31 that faces the semiconductor chip 20 and a second portion (i.e., a second region) 32 that is formed on an outer circumference side of the semiconductor chip 20 (e.g., an outer circumference side of the first to third semiconductor chips 20A, 20B, and 20C).

The lower insulating layer 40 is laminated on the semiconductor chip 20 and the resin mold 30. The lower insulating layer 40 includes a first portion (i.e., a first region) 41 and a second portion (i.e., a second region) 42. The first portion 41 is formed between the semiconductor chip 20 and the first redistribution layer 50. The first portion 41 overlaps the semiconductor chip 20 in a thickness direction of the lower insulating layer 40 (i.e., a lamination direction of the lower insulating layer 40 with respect to the semiconductor chip 20). On the other hand, the second portion 42 is formed between the second portion 32 of the resin mold 30 and the first redistribution layer 50. The second portion 42 overlaps the second portion 32 of the resin mold 30 in the thickness direction of the lower insulating layer 40. The lower insulating layer 40 is made of an insulating material 40m. The insulating material 40m is, for example, an acrylic resin, an oxetane resin, an epoxy resin, a polyimide resin or a polybenzoxazole resin, but not limited thereto. The lower insulating layer 40 may be referred to as a “base insulating layer.” However, this name does not limit the position, function, or configuration of the lower insulating layer 40. The lower insulating layer 40 is an example of a “third insulating layer.”

The first redistribution layer 50 is formed on a surface of the lower insulating layer 40. The first redistribution layer 50 is formed between the lower insulating layer 40 and the upper insulating layer 70. The first redistribution layer 50 is a layer including a plurality of conductive lines 51 (i.e., first interconnects 51) that are electrically connected to the conductive pads 21 of the semiconductor chip 20. The conductive line 51 is formed on the lower insulating layer 40. The conductive line 51 is formed between the semiconductor chip 20 and the upper insulating layer 70. The conductive line 51 is a part of an electrical connection between the conductive pad 21 and the solder connector 90. Electrical signals of the semiconductor chip 20 flow in the plurality of conductive lines 51. The “electrical signal of a semiconductor chip” referred to herein includes at least one of an electrical signal from the semiconductor chip 20 (e.g., an electrical signal sent from the semiconductor chip 20) and an electrical signal to the semiconductor chip 20 (e.g., an electrical signal to be received by the semiconductor chip 20). The conductive line 51 is an example of a “first inter connect (e.g., a first redistribution pattern).” For example, some of the plurality of conductive lines 51 extend over the first portion 41 and the second portion 42 of the lower insulating layer 40. The conductive line 51 is an example of a “first conductive portion.” The conductive line 51 is opposite to the semiconductor chip 20 (i.e., opposite to the conductive pad 21) with respect to the lower insulating layer 40.

The first redistribution layer 50 includes first vias 52 and via receiving portions (i.e., via connection portions) 53 in addition to the conductive lines 51. The first via 52 is in the lower insulating layer 40. The first via 52 is, for example, a via that has a bottom. The first via 52 is physically and electrically connected to at least one of the conductive lines 51. The first via 52 includes a recess 52a that is depressed into the lower insulating layer 40. The first via 52 extends from the conductive line 51 toward the semiconductor chip 20 (i.e., extends toward the resin mold 30) and penetrates through the lower insulating layer 40. The first via 52 may be physically connected to the conductive pad 21 of the semiconductor chip 20. The first via 52 is electrically connected to the conductive pad 21 of the semiconductor chip 20. The conductive line 51 is electrically connected to the conductive pad 21 of the semiconductor chip 20 through the first via 52. The via 52 is an example of a “second conductive portion.” Inside the recess 52a of the first via 52, a part of the upper insulating layer 70 is accommodated.

The via receiving portion 53 is a portion, within the first redistribution layer 50, to which a second via 82 of the second redistribution layer 80 is connected. The via receiving portion 53 is formed on the lower insulating layer 40. The via receiving portion 53 faces the second via 82 in a thickness direction of the upper insulating layer 70 (i.e., a lamination direction of the upper insulating layer 70 with respect to the first redistribution layer 50) and may be physically connected to the second via 82. The via receiving portion 53 is electrically connected to the second via 82. The via receiving portion 53 is another example of a “conductor.” The via receiving portion 53 is physically and electrically connected to at least one of the conductive lines 51. As a result, the via receiving portion 53 is electrically connected to the first via 52 through at least one of the conductive lines 51.

From a different point of view, the first redistribution layer 50 is a layer that is formed to be connected to the semiconductor chip 20 as conductive lines to send and receive electrical signals to and from the semiconductor chip 20. The first redistribution layer 50 is made of a conductive material (e.g., a conductive metal) 50m. The conductive material 50m is, for example, Au, Ni, Cu, Pt, Sn, or Pd, but not limited thereto. In the present embodiment, the conductive material 50m is Cu. The conductive material 50m is an example of a “first conductive material.” The first redistribution layer 50 is formed by, for example, a plating treatment. The conductive material 50m may be the same as or different from the conductive material 21m forming the conductive pad 21.

The molecular bonding layer 60 is formed on at least a part of a surface of the first redistribution layer 50. In the present embodiment, the molecular bonding layer 60 is formed on substantially the entire surface of the first redistribution layer 50. The molecular bonding layer 60 is formed between the first redistribution layer 50 and the upper insulating layer 70. The molecular bonding layer 60 is an example of a “first molecular bonding layer.” The molecular bonding layer 60 will be described below in detail.

The upper insulating layer 70 is formed on a side opposite to the lower insulating layer 40 with respect to the first redistribution layer 50. The upper insulating layer 70 is formed between the semiconductor chip 20 and at least one of the solder connectors 90. The upper insulating layer 70 is an example of a “first insulating layer.” The upper insulating layer 70 covers at least a part of the molecular bonding layer 60. In the present embodiment, the upper insulating layer 70 covers substantially the entire molecular bonding layer 60. The upper insulating layer 70 includes a first portion (i.e., a first region) 71 that overlaps the first portion 41 of the lower insulating layer 40 and a second portion (i.e., a second region) 72 that overlaps the second portion 42 of the lower insulating layer 40. The upper insulating layer 70 is made of an insulating material 70m. The insulating material 70m is, for example, an acrylic resin, an oxetane resin, an epoxy resin, a polyimide resin or a polybenzoxazole resin, but not limited thereto. The insulating material 70m is an example of a “first insulating material.” The insulating material 70m may be the same as or different from the insulating material 40m forming the lower insulating layer 40.

The second redistribution layer 80 is formed on a surface of the upper insulating layer 70. The second redistribution layer 80 is formed on a side opposite to the first redistribution layer 50 with respect to the upper insulating layer 70. The second redistribution layer 80 is electrically connected to the conductive lines 51 of the first redistribution layer 50. In addition, in the present embodiment, the second redistribution layer 80 includes terminal portions 81 that are formed on an outer surface of the semiconductor package 10. If the semiconductor package 10 does not have solder connectors 90, the terminal portion 81 is an example of a “first terminal.” The terminal portion 81 includes the second via 82. The second via 82 is in the upper insulating layer 70. The second via 82 is, for example, a via that has a bottom. The second via 82 includes a recess 82a that is depressed into the upper insulating layer 70. The second via 82 extends toward the first redistribution layer 50 and penetrates through the upper insulating layer 70. The second via 82 may be physically connected to the via receiving portion 53 of the first redistribution layer 50. The second via 82 is electrically connected to the via receiving portion 53 of the first redistribution layer 50. That is, the second redistribution layer 80 is electrically connected to the conductive lines 51 of the first redistribution layer 50. In addition, the second redistribution layer 80 is electrically connected to the conductive pads 21 of the semiconductor chip 20 through the first redistribution layer 50. The second redistribution layer 80 is made of a conductive material (e.g., a conductive metal) 80m. The conductive material 80m is, for example, Au, Ni, Cu, Pt, Sn, or Pd, but not limited thereto. In the present embodiment, the conductive material 80m is Cu. The conductive material 80m is an example of a “second conductive material.” The second redistribution layer 80 is formed by, for example, a plating. The conductive material 80m may be the same as or different from the conductive material 50m forming the first redistribution layer 50 and the conductive material 21m forming the conductive pad 21.

The solder connector 90 is an example of each of a “first terminal”, a “connector” or an “external connection terminal.” The solder connector 90 is a connection portion to physically and electrically connect an external module (e.g., a circuit board) and the semiconductor package 10. The solder connector 90 is formed in the terminal portion 81 of the second redistribution layer 80. A part of the solder connector 90 is accommodated inside the second via 82 of the terminal portion 81. The solder connector 90 is, for example, a solder ball or a solder bump. The “connection portion” is not limited to the solder connector and may be a conductor formed by conductive paste or other types of conductor.

Next, the molecular bonding layer 60 will be described.

As shown in FIG. 2, the molecular bonding layer 60 is formed between the first redistribution layer 50 and the upper insulating layer 70. The molecular bonding layer 60 is chemically bonded to both the first redistribution layer 50 and the upper insulating layer 70. That is, the molecular bonding layer 60 bonds the first redistribution layer 50 to the upper insulating layer 70. In the present embodiment, the molecular bonding layer 60 bonds a part of the first insulating layer 40 to the upper insulating layer 70. Although the molecular bonding layer 60 is actually very thin, it is drawn in FIG. 2 with a discernable thickness for convenience of description.

The molecular bonding layer 60 includes molecular systems 60r (refer to FIG. 3) formed by a molecular bonding agent. The molecular bonding agent is a compound capable of forming, for example, a chemical bond (e.g., a covalent bond) with a resin and a metal. Also, “covalent bond” herein broadly refers to a bond having a covalent bonding property and includes a coordinate bond, a semi-covalent bond and the like. In addition, “molecular system” herein refers to a substance that remains in a bonding part after a molecular bonding agent is chemically bonded (i.e., chemically reacted).

As the molecular bonding agent, for example, a compound such as a triazine derivative may be exemplified. As the triazine derivative, a compound expressed by the following General Formula (C1) may be exemplified.

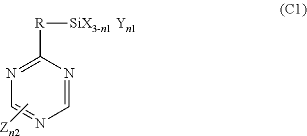

(where, R represents a hydrocarbon group or a hydrocarbon group which may include a hetero atom or a functional group therebetween; X represents a hydrogen atom or a hydrocarbon group; Y represents an alkoxy group; Z represents a thiol group, an amino group or an azido group, which may be a salt, or a hydrocarbon group which may include a hetero atom or a functional group therebetween; n1 represents an integer of 1 to 3; and n2 represents an integer of 1 to 2.)

In General Formula (C1), R is preferably a hydrocarbon group having 1 to 7 carbon atoms or a group having a main chain in which a nitrogen atom is included. X represents a hydrocarbon group having 1 to 3 carbon atoms. Y represents an alkoxy group having 1 to 3 carbon atoms. n1 is preferably 3. n2 is preferably 2. Z preferably represents a thiol group, an amino group or an azido group, which may be a salt, or an alkyl group. As a cation element that forms a salt, an alkali metal is preferable. Among alkali metals, Li, Na, K or Cs is more preferable. When n2 is 2, at least one Z is preferably a thiol group, an amino group or an azido group, which is a salt.

At least a part of the molecular bonding layer 60 (i.e., at least a part of a molecular bonding agent that forms the molecular bonding layer 60) is chemically bonded (e.g., covalently bonded) to the conductive material 50m included in the conductive line 51 of the first redistribution layer 50. Similarly, at least a part of the molecular bonding layer 60 (i.e., at least a part of a molecular bonding agent that forms the molecular bonding layer 60) is chemically bonded (e.g., covalently bonded) to the insulating material 70m included in the upper insulating layer 70. As a result, the molecular bonding layer 60 bonds the conductive line 51 of the first redistribution layer 50 to the upper insulating layer 70.

When the molecular bonding agent is chemically bonded (e.g., covalently bonded) to the conductive material 50m of the conductive line 51 of the first redistribution layer 50 and the insulating material 70m of the upper insulating layer 70, the conductive line 51 of the first redistribution layer 50 and the upper insulating layer 70 can be bonded with a strong adhesive force. As a result, in a reflow process for connecting the solder connectors 90 to an external module, it is possible to suppress peeling off of the upper insulating layer 70 from the first redistribution layer 50.

FIG. 3 schematically illustrates of a composition of the molecular bonding layer 60. As shown in FIG. 3, the molecular bonding layer 60 includes, for example, a plurality of molecular systems 60r. The molecular system 60r includes a molecular bonding agent residue that is formed when the above-described molecular bonding agent is chemically reacted with bonding targets (a first member and a second member). For example, the molecular system 60r includes a molecular bonding agent residue that is formed when the above-described molecular bonding agent is chemically reacted with the first redistribution layer 50 and the upper insulating layer 70. The molecular bonding agent residue is, for example, a triazine dithiol residue, as shown in FIG. 3. The molecular system 60r may include “S” or “Z” in FIG. 3. An example of “Z” in FIG. 3 is an amino hydrocarbylsiloxy group. For example, at least one of the molecular systems 60r included in the molecular bonding layer 60 is chemically bonded (e.g., covalently bonded) to both the conductive material 50m included in the conductive line 51 of the first redistribution layer 50 and the insulating material 70m included in the upper insulating layer 70. In other words, one molecule of the molecular bonding agent (e.g., the molecular system 60r) included in the molecular bonding layer 60 is chemically bonded (e.g., covalently bonded) to both the conductive material 50m included in the conductive line 51 of the first redistribution layer 50 and the insulating material 70m included in the upper insulating layer 70.

As shown in FIG. 2, in the present embodiment, the molecular bonding layer 60 includes a first portion 61, a second portion 62, and a third portion 63. As described above, the first portion 61 is formed between the conductive line 51 of the first redistribution layer 50, and the upper insulating layer 70 and is chemically bonded (e.g., covalently bonded) to both the conductive line 51 of the first redistribution layer 50 and the upper insulating layer 70. That is, the first portion 61 bonds the conductive line 51 of the first redistribution layer 50 and the upper insulating layer 70.

The second portion 62 is formed inside the recess 52a of the first via 52. The second portion 62 is formed on an inner surface of the recess 52a of the first via 52 (i.e., an inner surface of the first via 52) and extends in a direction different from that of the first portion 61. The second portion 62 extends, for example, in a direction crossing a boundary surface between the semiconductor chip 20 and the lower insulating layer 40. The second portion 62 is formed between the inner surface of the first via 52 and the upper insulating layer 70 and is chemically bonded (e.g., covalently bonded) to both the first via 52 and the upper insulating layer 70. More specifically, at least a part of the second portion 62 (i.e., at least a part of a molecular bonding agent that forms the molecular bonding layer 60) is chemically bonded (e.g., covalently bonded) to the conductive material 50m included in the first via 52. Similarly, at least a part of the second portion 62 (i.e., at least a part of a molecular bonding agent that forms the molecular bonding layer 60) is chemically bonded (e.g., covalently bonded) to the insulating material 70m included in the upper insulating layer 70 inside the recess 52a of the first via 52. That is, the second portion 62 bonds the first via 52 to the upper insulating layer 70 inside the recess 52a of the first via 52.

The third portion 63 is formed between the via receiving portion 53 of the first redistribution layer 50 and the second via 82 of the second redistribution layer 80 and is chemically bonded (e.g., covalently bonded) to both the via receiving portion 53 of the first redistribution layer 50 and the second via 82 of the second redistribution layer 80. More specifically, at least a part of the third portion 63 (i.e., at least a part of a molecular bonding agent that forms the molecular bonding layer 60) is chemically bonded (e.g., covalently bonded) to the conductive material 50m included in the via receiving portion 53 of the first redistribution layer 50. Similarly, at least a part of the third portion 63 (i.e., at least a part of a molecular bonding agent that forms the molecular bonding layer 60) is chemically bonded (e.g., covalently bonded) to the conductive material 80m included in the second via 82. That is, the molecular bonding layer 60 bonds the via receiving portion 53 of the first redistribution layer 50 to the second via 82 of the second redistribution layer 80.

Here, the molecular systems 60r of the molecular bonding layer 60 are not completely uniformly dispersed. The second via 82 of the second redistribution layer 80 is in contact with the via receiving portion 53 of the first redistribution layer 50 at positions (i.e., regions in which the molecular system 60r is not present) between the plurality of molecular systems 60r. As a result, the second via 82 of the second redistribution layer 80 and the via receiving portion 53 of the first redistribution layer 50 are electrically connected.

An adhesion strength between the first redistribution layer 50 and the upper insulating layer 70 is preferably 2 MPa or more, more preferably 5 MPa or more, still more preferably 6 MPa or more, and most preferably 10 MPa or more. In addition, a breaking mode when the adhesion strength is measured is preferably a mode in which the upper insulating layer 70 rather than a bonding interface is broken. The adhesion strength can be measured by, for example, a die shear test. A specific example of a tensile test includes methods defined in MIL-STD883G, IEC-60749-19, EIAJ ED-4703, and the like. In addition, from a different point of view, the adhesion strength between the first redistribution layer 50 and the upper insulating layer 70 is preferably 0.5 N/mm or more and more preferably 1 N/mm or more. The adhesion strength can be measured by, for example, a peel strength test. As a specific example of the test, the methods defined in JISC5012 are exemplary examples.

The molecular bonding layer 60 may have a thickness of 0.5 nm or more, and preferably 1 nm or more and 20 nm or less. The thickness of the molecular bonding layer 60 is more preferably, for example, 1 nm or more and 10 nm or less.

A coverage ratio of the molecular bonding agent (i.e., a covering ratio of the molecular bonding layer 60) with respect to an area of the conductive line 51 of the first redistribution layer 50 is 20% or more, preferably 30% or more, and more preferably 50% or more. For example, the coverage ratio of the molecular bonding agent with respect to the area of the conductive line 51 of the first redistribution layer 50 is 80% or less. That is, the coverage ratio of the molecular bonding agent with respect to the area of the conductive line 51 of the first redistribution layer 50 is, for example, 20 to 80%, preferably 30 to 80%, and more preferably 50 to 80%. Also, when the coverage ratio of the molecular bonding agent is 100 area %, it means that the molecular bonding agent is packed theoretically closest with respect to a surface of a target to be covered. The coverage ratio of the molecular bonding agent can be obtained based on results measured by an X-ray diffraction method.

If the coverage ratio of the molecular bonding agent with respect to the area of the conductive line 51 of the first redistribution layer 50 is the lower limit value or more, adhesiveness between the first redistribution layer 50 and the upper insulating layer 70 can be further increased. In addition, if the coverage ratio of the molecular bonding agent with respect to the area of the conductive line 51 of the first redistribution layer 50 is the upper limit value or less, an electrical connection between the via receiving portion 53 of the first redistribution layer 50 and the second via 82 of the second redistribution layer 80 can be ensured.

For example, at least a part of the molecular bonding layer 60 has a monomolecular film form. That is, the molecular bonding layer 60 consists at least in part of a monomolecular layer. In the present embodiment, substantially the entire molecular bonding layer 60 is formed in a monomolecular film form. In a portion that is formed in a monomolecular film form in the molecular bonding layer 60, one molecule agent (i.e., the molecular system 60r) of the molecular bonding is chemically bonded (e.g., covalently bonded) to both the conductive material 50m of the first redistribution layer 50 and the insulating material 70m of the upper insulating layer 70. As a result, adhesiveness between the first redistribution layer 50 and the upper insulating layer 70 can be further increased. Further, an increase in the thickness of the semiconductor package 10 due to the molecular bonding layer 60 is minimized. Portions occupying most areas of the molecular bonding layer 60 preferably have monomolecular film forms. For example, within the surface of the first redistribution layer 50, a portion corresponding to 30 to 100% of an area covered by the molecular bonding layer 60 more preferably has a mono-molecular film form.

Here, in a case where an insulating layer is formed on a redistribution layer, a surface of a conductive line of a redistribution layer may be made coarser by etching. Thereby, it is possible to ensure adhesiveness between the conductive line of the redistribution layer and the insulating layer according to an anchor effect. However, in semiconductor packages (e.g., an FOWLP or a WLCSP) that are required to be smaller, formation of a fine wiring pattern (i.e., a fine pattern) is required. In this case, when the surface of the conductive line of the redistribution layer is etched, the conductive line becomes thinner and it becomes more difficult to form a fine wiring pattern.

In this respect, according to the present embodiment, by forming the molecular bonding layer 60, adhesiveness between the conductive line 51 of the redistribution layer 50 and the insulating layer 70 is ensured. That is, according to the present embodiment, there is no need to make the surface of the conductive line 51 of the redistribution layer 50 coarser by etching. For that reason, the conductive line 51 is not likely to become thinner and the conductive line 51 of the redistribution layer 50 can be formed into a fine wiring pattern.

Next, a method of producing the semiconductor package 10 according to the present embodiment will be described.

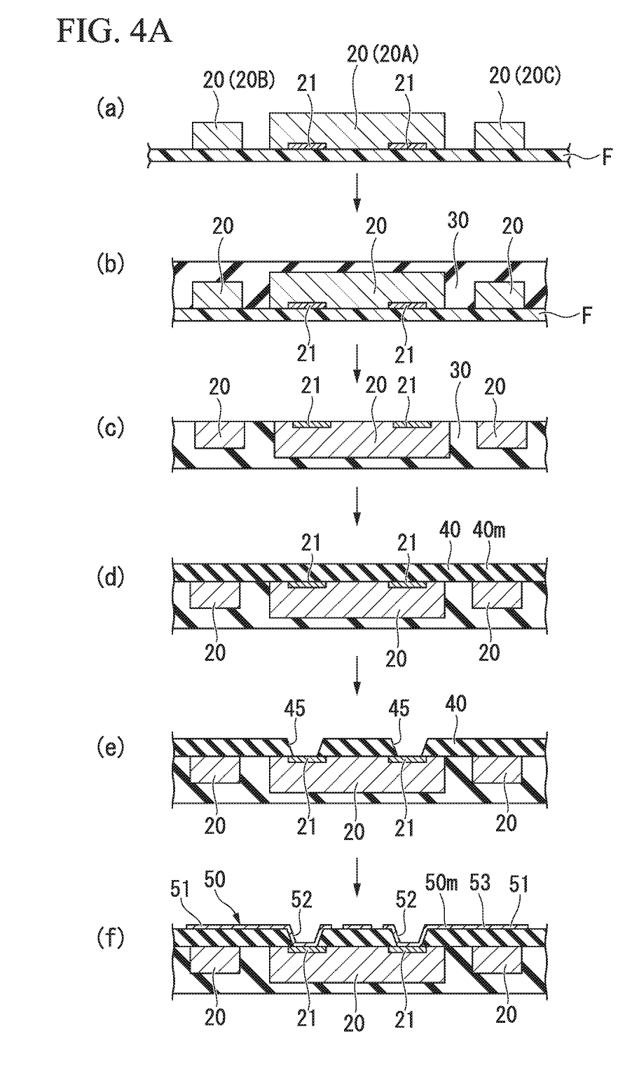

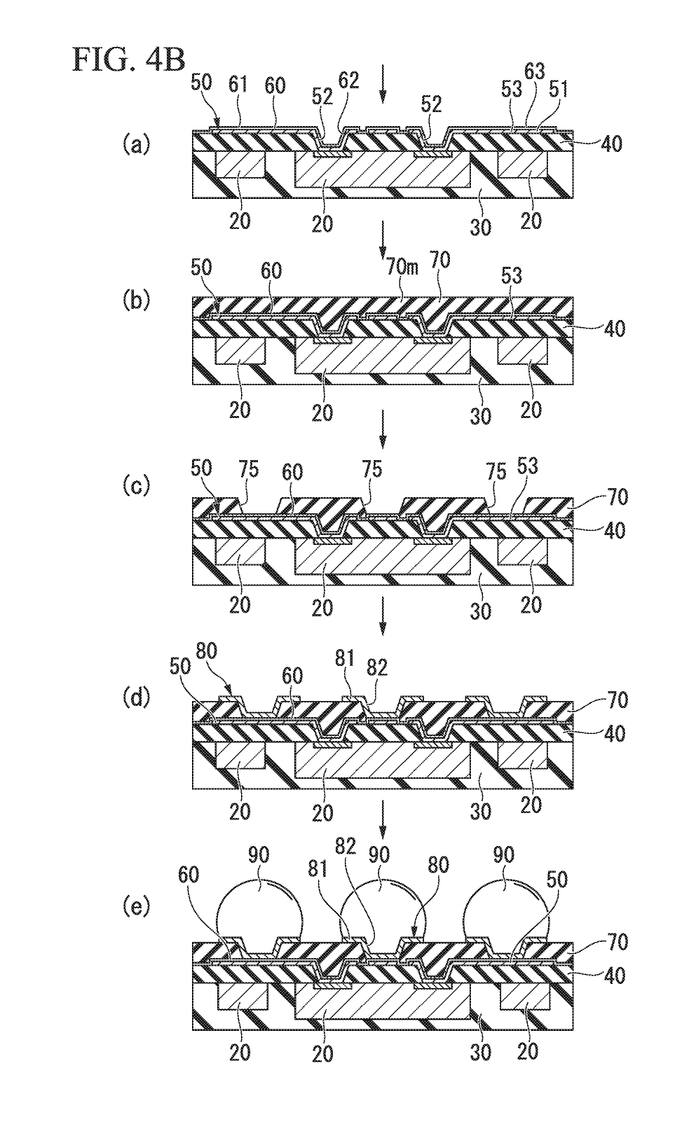

FIG. 4A and FIG. 4B are cross-sectional views of a structure in process to show a flow of a method of producing the semiconductor package 10 according to the present embodiment.

First, the semiconductor chip 20 is placed on a film F ((a) in FIG. 4A). Next, an insulating material that becomes the resin mold 30 is supplied over the semiconductor chip 20 (e.g., over the first to third semiconductor chips 20A, 20B, and 20C). As a result, the resin mold 30 is formed ((b) in FIG. 4A). Next, an intermediate product produced by the above-described process is inverted (upside down), and the film F is removed ((c) in FIG. 4A).

Next, the insulating material 40m is formed on the semiconductor chip 20 (e.g., the first to third semiconductor chips 20A, 20B, and 20C) and the resin mold 30. As a result, the lower insulating layer 40 is formed ((d) in FIG. 4A). Next, openings 45 (i.e., through holes) are formed in the lower insulating layer 40 ((e) in FIG. 4A). The opening 45 is formed in a region corresponding to the conductive pad 21 of the semiconductor chip 20 and penetrates through the lower insulating layer 40. The opening 45 is formed by etching, for example, the lower insulating layer 40. Next, the first redistribution layer 50 is formed on the lower insulating layer 40 ((f) in FIG. 4A). The first redistribution layer 50 includes the conductive lines 51, the first vias 52, and the via receiving portions 53. For example, the first redistribution layer 50 is formed by a metal plating treatment. The metal plating treatment includes, for example, forming a seed layer of, for example, palladium, by sputtering, and performing electrolytic plating or electroless plating on the seed layer. Also, a method of forming the first redistribution layer 50 is not limited to the above example. Several examples of a method of forming the first redistribution layer 50 will be described in detail in the second to fourth embodiments.

Next, the molecular bonding layer 60 is formed on the surface of the first redistribution layer 50 ((a) in FIG. 4B). For example, the molecular bonding layer 60 is formed by at least covering the surfaces of the first redistribution layer 50 with the molecular bonding agent (i.e., by applying the molecular bonding agent to the surfaces of the first redistribution layer 50). For example, the molecular bonding agent is applied to surfaces of the conductive lines 51, the first vias 52 (e.g., bottom surfaces and the inner surfaces of the first vias 52), and the via receiving portions 53 of the first redistribution layer 50. The molecular bonding layer 60 is formed, for example, by at least applying a molecular bonding agent solution including the above-described molecular bonding agent onto the first redistribution layer 50. The method of applying the molecular bonding agent solution includes a method of immersing the intermediate product produced by the above process in the molecular bonding agent solution and a method of spraying the molecular bonding agent solution on the first redistribution layer 50.

When the surface of the first redistribution layer 50 is covered with the molecular bonding agent, the molecular bonding agent solution is preferably used. The molecular bonding agent solution can be prepared by dissolving the above-described molecular bonding agent in a solvent.

Exemplary solvents include, for example, water; alcohols such as methanol, ethanol, isopropanol, ethylene glycol, propylene glycol, cellosolve and carbitol; ketones such as acetone, methyl ethyl ketone and cyclohexanone; aromatic hydrocarbons such as benzene, toluene and xylene; aliphatic hydrocarbons such as hexane, octane, decane, dodecane and octadecane; esters such as ethyl acetate, methyl propionate and methyl phthalate; and ethers such as tetrahydrofuran, ethyl butyl ether and anisole. In addition, a mixture of such solvents are can be used.

A concentration of the molecular bonding agent solution is preferably 0.001 mass % or more and 1 mass % or less and more preferably 0.01 mass % or more and 0.1 mass % or less with respect to a total mass of the molecular bonding agent solution. If the concentration of the molecular bonding agent solution is the lower limit value or more, it is possible to further increase the coverage ratio of the molecular bonding agent and adhesiveness between members. If the concentration of the molecular bonding agent solution is the upper limit value or less, since a molecular bonding agent that does not chemically bond (e.g., covalently bond) is not likely to be included in the adhesive portion, it is possible to ensure adhesion between the first redistribution layer 50 and the upper insulating layer 70. In addition, it is possible to suppress an increase in thickness of the semiconductor package 10 due to the molecular bonding layer 60.

The prepared molecular bonding agent solution is applied to the surface of the first redistribution layer 50. While the intermediate product to which the molecular bonding agent solution is applied is left, chemical bonding (e.g., covalent bonding) between the conductive material 50m of the conductive line 51 of the first redistribution layer 50 and the molecular bonding agent is promoted. Further, an operation of applying energy (e.g., heat or light (e.g., ultraviolet rays)) to the molecular bonding layer 60 may be performed. For example, the intermediate product to which the molecular bonding agent solution is applied may be heated to a certain temperature for a certain period of time and dried. According to the operation of applying energy, chemical bonding (e.g., covalent bonding) between the conductive material 50m included in the first redistribution layer 50 and the molecular bonding agent is promoted. Then, when the intermediate product is cleaned using a cleaning solution and dried, the intermediate product in which the surface of the first redistribution layer 50 is covered with the molecular bonding agent is obtained. The cleaning solution may be the same as the solvent used for the molecular bonding agent solution.

The conductive material 50m of the first redistribution layer 50 covered with molecular bonding agent forms a chemical bond (e.g., a covalent bond) with the molecular bonding agent. That is, the molecular bonding layer 60 including the molecular bonding agent (e.g., the molecular systems 60r) that is chemically bonded (e.g., covalently bonded) to the conductive material 50m included in the first redistribution layer 50 is formed on the surface of the first redistribution layer 50. The “molecular bonding layer” described in the production method herein may refer to a molecular bonding layer, at least a part of which has not yet chemically reacted (e.g., has not chemically bonded), in addition to a molecular bonding layer that has chemically reacted (e.g., chemically bonded). The molecular bonding layer, at least a part of which has not yet chemically reacted, may also be understood as a “layer of the molecular bonding agent.”

The molecular bonding agent solution may be applied to not only the surface of the first redistribution layer 50 but also a portion in which the first redistribution layer 50 is not formed. When the lower insulating layer 40 is covered with the molecular bonding agent, the molecular bonding layer 60 including the molecular bonding agent (e.g., the molecular systems 60r) that is chemically bonded (e.g., covalently bonded) to the insulating material 40m included in the lower insulating layer 40 may be formed on the surface of the lower insulating layer 40.

The thickness of the molecular bonding layer 60 can be adjusted according to conditions such as the concentration, the applied amount of the molecular bonding agent solution, the cleaning time, and the number of cleanings.

Next, the insulating material 70m is formed on the molecular bonding layer 60. As a result, a surface of the molecular bonding layer 60 is covered with the insulating material 70m, and the upper insulating layer 70 is formed ((b) in FIG. 4B). Further, the insulating material 70m of the upper insulating layer 70 comes in contact with at least a part of the molecular bonding layer 60. The molecular bonding agent is also chemically bonded (e.g., covalently bonded) to the insulating material 70m of the upper insulating layer 70. As a result, the molecular bonding agent is chemically bonded (e.g., covalently bonded) to both the conductive material 50m of the first redistribution layer 50 and the insulating material 70m of the upper insulating layer 70. Here, an operation of applying energy to the molecular bonding layer 60 may be performed. As energy, for example, heat or light (e.g., ultraviolet rays) can be used. Thereby, it is possible to promote chemical bonding (e.g., covalent bonding) between the molecular bonding agent and the insulating material 70m of the upper insulating layer 70. The heating temperature and the heating time are appropriately determined according to the applied amount of the molecular bonding agent solution. If heat is used, heating at about 150 to 200° C. can be performed for 5 minutes or more, preferably 60 minutes or more, more preferably 80 minutes or more and 120 minutes or less, and most preferably 240 minutes or less. For example, depending on a material of the molecular bonding layer 60, heating may be applied for 5 minutes to 120 minutes, preferably 60 minutes to 240 minutes, and more preferably for 80 minutes to 240 minutes. If light is used, ultraviolet rays and the like can be used. In addition, a wavelength of the ultraviolet rays is preferably 250 nm or less and an emission time is appropriately determined according to an applied amount of the molecular bonding agent solution.

Next, openings 75 (i.e., through holes) are formed in the upper insulating layer 70 ((c) in FIG. 4B). The opening 75 is formed in a region corresponding to the via receiving portion 53 of the first redistribution layer 50 and penetrates through the upper insulating layer 70. The opening 75 is formed by etching, for example, the upper insulating layer 70. Next, the second redistribution layer 80 is formed on the upper insulating layer 70 ((d) in FIG. 4B). The second redistribution layer 80 includes the terminal portions 81. For example, the second redistribution layer 80 is formed by a metal plating treatment. The metal plating treatment includes, for example, forming a seed layer of, for example, palladium, by sputtering, and performing electrolytic plating or electroless plating on the seed layer. Also, a method of forming the second redistribution layer 80 is not limited to the above example. Several examples of a method of forming the second redistribution layer 80 will be described in detail in the second to fourth embodiments. Then, the solder connectors 90 are formed on the terminal portions 81 of the second redistribution layer 80 ((e) in FIG. 4B).

Also, chemical bonding (e.g., covalent bonding) of the molecular bonding agent may occur when no energy such as heat or light is applied. Alternatively, chemical bonding (e.g., covalent bonding) of the molecular bonding agent may occur when energy such as heat or light is applied.

Next, a modification example of the present embodiment will be described.

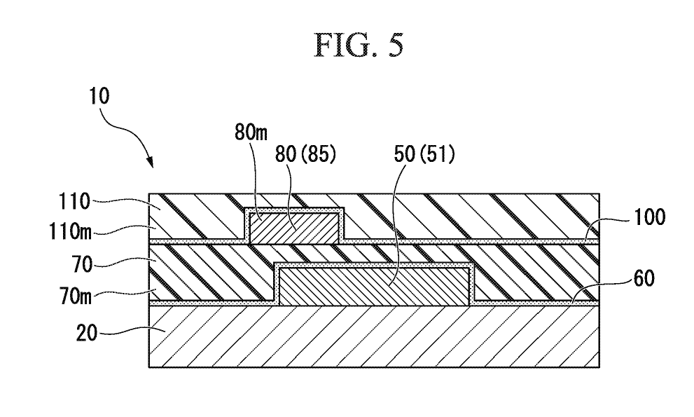

FIG. 5 is a cross-sectional view of a part of the semiconductor package 10 according to a modification example of the first embodiment. This modification example is different from the first embodiment in that the semiconductor package 10 includes a plurality of insulating layers covering a plurality of redistribution layers. Configurations not described below are the same as those in the first embodiment.

As shown in FIG. 5, the semiconductor package 10 of this modification example includes the semiconductor chip 20, the first redistribution layer 50, the first molecular bonding layer 60, the first insulating layer 70, the second redistribution layer 80, a second molecular bonding layer 100, and a second insulating layer 110. The first redistribution layer 50, the first molecular bonding layer 60, and the first insulating layer 70 are substantially the same as the first redistribution layer 50, the molecular bonding layer 60, and the upper insulating layer 70 of the first embodiment. At least a part of the conductive lines (i.e., the first interconnects) 51 of the first redistribution layer 50 may be formed on the surface of the semiconductor chip 20 in place of the surface of the lower insulating layer 40. The “surface of the semiconductor chip 20” referred to herein may be a surface of a passivation film formed on the semiconductor chip 20.

The second redistribution layer 80 is formed on a side opposite to the first redistribution layer 50 with respect to the first insulating layer 70. For example, the second redistribution layer 80 is formed on a surface of the first insulating layer 70. The second redistribution layer 80 is formed between the first insulating layer 70 and the second insulating layer 110. The second redistribution layer 80 is a layer including a plurality of second conductive lines (e.g., second interconnects) 85. The plurality of second conductive lines 85 are electrically connected to the conductive pads 21 of the semiconductor chip 20 through a plurality of first conductive lines 51 of the first redistribution layer 50. Electronic signals of the semiconductor chip 20 flows in the plurality of second conductive lines 85. The second redistribution layer 80 is made of the second conductive material (e.g., a conductive metal) 80m. The conductive material 80m may be the same as or different from the conductive material 50m that forms the first redistribution layer 50.

The second redistribution layer 80 includes the second vias 82 (refer to FIG. 2) in addition to the second conductive lines 85. The second via 82 is physically and electrically connected to the second conductive line 85. For example, the second via 82 is substantially the same as the second via 82 of the first embodiment. For example, the second conductive line 85 is electrically connected to the first conductive line 51 of the first redistribution layer 50 through the second via 82.

The second molecular bonding layer 100 is formed on a side opposite to the first insulating layer 70 with respect to the second redistribution layer 80. The second molecular bonding layer 100 is formed on at least a part of a surface of the second redistribution layer 80. The second molecular bonding layer 100 is formed between the second redistribution layer 80 and the second insulating layer 110. In this modification example, the second molecular bonding layer 100 is formed on substantially the entire surface of the second redistribution layer 80. Other description related to the second molecular bonding layer 100 would be understood as replacement of “the first redistribution layer 50” with “the second redistribution layer 80,” “the conductive line 51 (i.e., the first conductive line)” with “the second conductive line 85,” “the conductive material 50m (i.e., the first conductive material)” with “the second conductive material 80m,” “the upper insulating layer 70 (i.e., the first insulating layer)” with “the second insulating layer 110,” and “the insulating material 70m (i.e., the first insulating material)” with “a second insulating material 110m” in the descriptions related to the molecular bonding layer 60 of the first embodiment.

The second insulating layer 110 is formed on a side opposite to the first insulating layer 70 with respect to the second redistribution layer 80. The second insulating layer 110 is formed between the first insulating layer 70 and the solder connectors 90. The second insulating layer 110 covers at least a part of the second molecular bonding layer 100. In the present embodiment, the second insulating layer 110 covers substantially the entire second molecular bonding layer 100. The second insulating layer 110 is made of the second insulating material 110m. The second insulating material 110m is, for example, an acrylic resin, an oxetane resin or an epoxy resin, but not limited thereto. The second insulating material 110m may be the same as or different from the insulating material 70m forming the first insulating layer 70.

In other words, in the present embodiment, the semiconductor package 10 includes: the second redistribution layer 80 that is formed on the surface of the first insulating layer 70 and includes the second conductive lines 85 in which electrical signals of the semiconductor chip 20 flow; the second molecular bonding layer 100 that is formed on at least a part of the second redistribution layer 80; and the second insulating layer 110 that covers at least a part of the second redistribution layer 80. At least a part of the second molecular bonding layer 100 is chemically bonded (e.g., covalently bonded) to the conductive material 80m included in the second conductive line 85. At least a part of the second molecular bonding layer 100 is chemically bonded (e.g., covalently bonded) to the second insulating material 110m included in the second insulating layer 110.

Also, an additional redistribution layers and insulating layers may be further formed on a surface of the second insulating layer 110. For example, a third molecular bonding layer, a third redistribution layer and a third insulating layer, . . . an n-th molecular bonding layer, an n-th redistribution layer and an n-th insulating layer (n is an integer of 2 or more) may be additionally formed. In this case, configurations of the n-th molecular bonding layer, the n-th redistribution layer and the n-th insulating layer may be the same as configurations of the first molecular bonding layer 60, the first redistribution layer 50 and the first insulating layer 70.

In addition, in the modification example, the molecular bonding layer 60 may be formed in a portion in which the first redistribution layer 50 is not formed on the surface of the semiconductor chip 20. That is, this portion and the first insulating layer 70 may be bonded by the molecular bonding layer 60. Similarly, the molecular bonding layer may be formed in a portion in which an n-th redistribution layer is not formed on a surface of an (n−1)-th insulating layer on which an n-th wiring layer is formed. That is, this portion and an n-th insulating layer placed on an (n−1)-th insulating layer may be bonded by the n-th molecular bonding layer.

In addition, when the n-th redistribution layer, the n-th molecular bonding layer and the n-th insulating layer are formed (e.g., when the second redistribution layer 80, the second molecular bonding layer 100, and the second insulating layer 110 are formed), the same process as the process of forming the first redistribution layer 50, the molecular bonding layer 60, and the upper insulating layer 70 described in the first embodiment is also repeatedly performed. In the modification example, the second redistribution layer 80 is formed on the surface of the first insulating layer 70, the second molecular bonding layer 100 is formed on the surface of the first redistribution layer 50, and the second insulating layer 110 is formed on a surface of the second molecular bonding layer 100 according to the same process as described above. Note that a molecular bonding agent (i.e., a first molecular bonding agent) forming the first molecular bonding layer 60 and a molecular bonding agent (i.e., a second molecular bonding agent) forming the second molecular bonding layer 100 may be the same as or different from each other.

### Second Embodiment

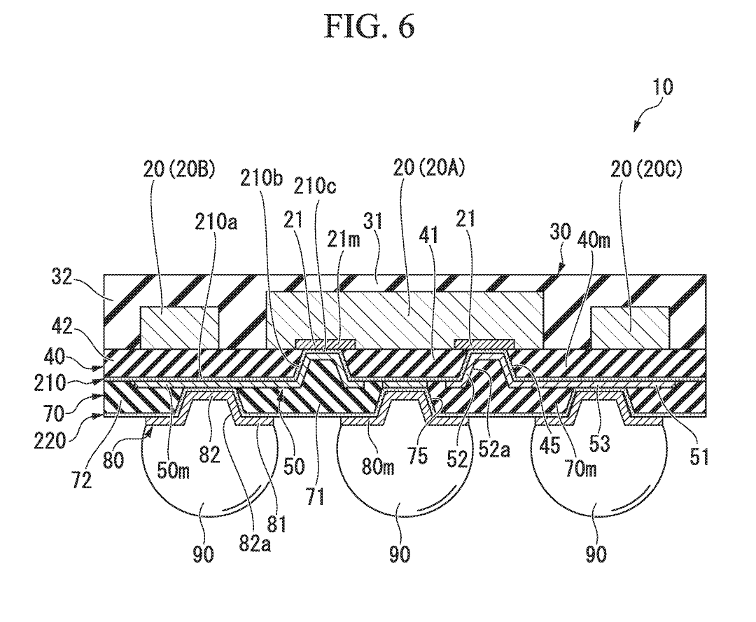

A second embodiment will be described with reference to FIG. 6 to FIG. 8J. The second embodiment is different from the first embodiment in that a molecular bonding layer is formed for a metal plating treatment. Configurations not described below are the same as those in the first embodiment.

FIG. 6 is a cross-sectional view of the semiconductor package 10 according to the second embodiment.

As shown in FIG. 6, the semiconductor package 10 according to the second embodiment includes a third molecular bonding layer 210 and a fourth molecular bonding layer 220 in addition to the configuration of the semiconductor package 10 according to the first embodiment. Here, in FIG. 6, for convenience of description, the first molecular bonding layer 60 described in the first embodiment is not shown. The semiconductor package 10 of the second to fourth embodiments may include or may not include the first molecular bonding layer 60 and the second molecular bonding layer 100 described in the first embodiment. In one aspect, the third molecular bonding layer 210 may be referred to as a “first molecular bonding layer.” Also, the fourth molecular bonding layer 220 may be referred to as a “second molecular bonding layer.”

As shown in FIG. 6, the third molecular bonding layer 210 is formed between the lower insulating layer 40 and the first redistribution layer 50, and is chemically bonded to both the lower insulating layer 40 and the first redistribution layer 50. As a result, the third molecular bonding layer 210 bonds the lower insulating layer 40 to the first redistribution layer 50. In other words, the third molecular bonding layer 210 is formed on at least a surface of the lower insulating layer 40. The first redistribution layer 50 is formed by the metal plating treatment being performed on the third molecular bonding layer 210, and is bonded to the surface of the lower insulating layer 40 by the third molecular bonding layer 210.

On the other hand, the fourth molecular bonding layer 220 is formed between the upper insulating layer 70 and the second redistribution layer 80 and is chemically bonded to both the upper insulating layer 70 and the second redistribution layer 80. As a result, the fourth molecular bonding layer 220 bonds the upper insulating layer 70 to the second redistribution layer 80. In other words, the fourth molecular bonding layer 210 is formed on at least a surface of the upper insulating layer 70. The second redistribution layer 80 is formed by the metal plating treatment being performed on the fourth molecular bonding layer 220, and is bonded to the surface of the upper insulating layer 70 by the fourth molecular bonding layer 220.

Hereinafter, the third molecular bonding layer 210 will be described in detail. Since the fourth molecular bonding layer 220 is substantially the same as the third molecular bonding layer 210, details will not be described. In addition, in the following description, “the third molecular bonding layer 210” will be simply referred to as “the molecular bonding layer 210.” In addition, “the lower insulating layer 40” will be simply referred to as “the insulating layer 40.”

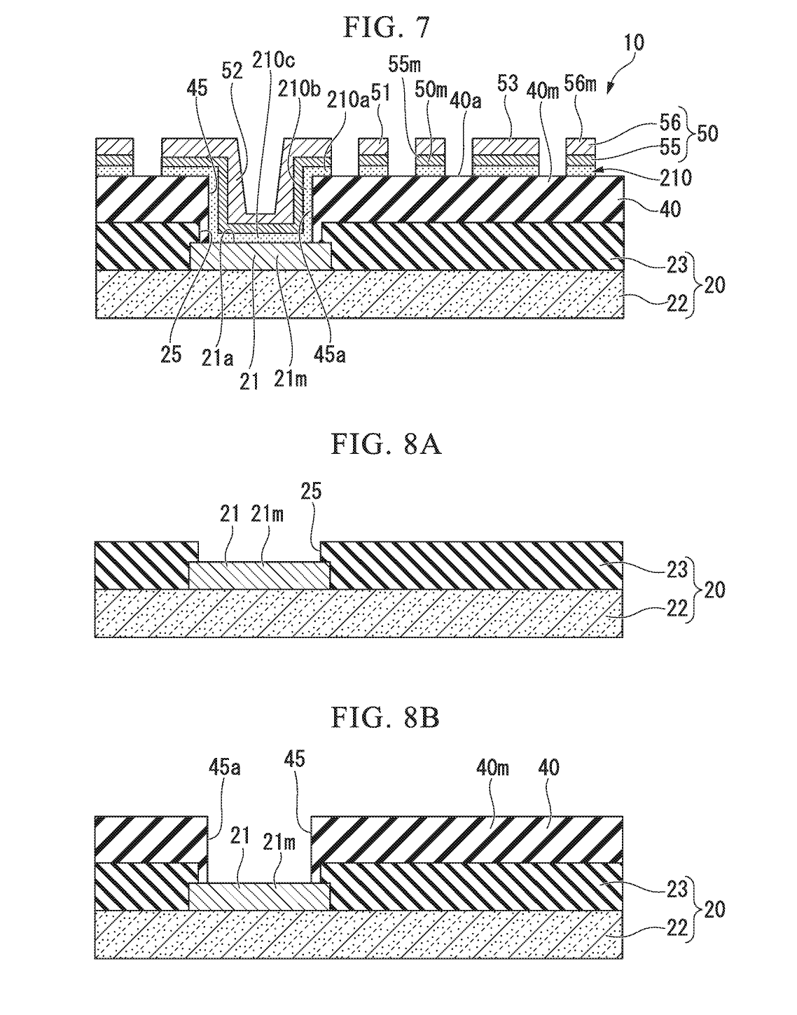

FIG. 7 is an enlarged cross-sectional view of a vicinity of the molecular bonding layer 210.

As shown in FIG. 7, the semiconductor package 10 includes the semiconductor chip (i.e., a semiconductor device component) 20, the insulating layer 40, the molecular bonding layer 210, and the first redistribution layer 50. Also, in the following description, for convenience of description, the first redistribution layer 50 will be referred to as a metal plating layer 50. The “metal plating layer” referred to herein is not limited to a redistribution layer and may be a plating layer used for other purposes (e.g., a ground layer, or for product protection or decoration).

The semiconductor chip 20 includes, for example, a semiconductor substrate 22, the conductive pad 21, and an insulating film 23.

The semiconductor substrate 22 is made of a semiconductor and is a member on which an electric circuit has been formed by a previous process. Examples of the semiconductor substrate 22 include a Si single crystal substrate, a Si epitaxial substrate, a GaAs substrate and a GaP substrate. Among them, the Si single crystal substrate and the Si epitaxial substrate are preferable in light of availability.

The conductive pad 21 is a terminal through which electrical signals of the semiconductor substrate 22 (i.e., electrical signals of the semiconductor chip 20) flow. The conductive pad 21 is an example of a “conductor.” As described above, the conductive pad 21 is made of metal (i.e., the metal material) 21m. The metal 21m is, for example, copper, a copper alloy, aluminum or an aluminum alloy (e.g., an aluminum-silicon based alloy), but not limited thereto. A side surface of the conductive pad 21 is in contact with the insulating film 23. In addition, the insulating film 23 may be formed on a peripheral part of the conductive pad 21. A thickness of the conductive pad 21 is not particularly limited and is preferably, for example, 0.1 μm or more and 10 μm or less.

The insulating film 23 is a resin film, or an oxide film or a nitride film made of a semiconductor material of the semiconductor substrate 22, and is also referred to as a passivation film. The resin film 23 is made of a resin material such as a polyimide. The resin film can be formed by photolithography using a resin material. The oxide film is made from an oxide of a semiconductor. The oxide film can be generated by oxidizing a surface of the semiconductor substrate 22 using an oxidizing gas such as water vapor. In addition, the nitride film is made of a nitride of a semiconductor. The nitride film can be generated by nitriding a surface of the semiconductor substrate 22 using a nitrogen-containing gas such as ammonia.

The insulating film 23 has an opening 25 through which at least a part of the conductive pad 21 is exposed. The “opening (or a hole)” referred to herein may be any opening that is open in at least a certain period of time during a process of producing the semiconductor package 10 and also includes an opening that is filled by another member when the semiconductor package 10 is completed. In addition, the opening 25 is an example of an “exposing portion.” A thickness of the insulating film 23 is not particularly limited and is preferably, for example, 1 μm or more and 10 μm or less. In addition, the thickness of the insulating film 23 may be uniform or non-uniform. For example, the thickness of the insulating film 23 may decrease from a position of the opening to the outside. That is, the insulating film 23 may have a slope shape.

The insulating layer (e.g., an insulating resin layer) 40 is a member that forms an insulating portion with respect to the semiconductor chip 20. The insulating layer 40 is formed on the insulating film 23 and the peripheral part of the conductive pad 21. The insulating layer 40 includes the opening 45 at a position corresponding to the conductive pad 21. The “opening (or a hole)” referred to herein may be any opening that is open in at least a certain time during a process of producing the semiconductor package 10 and also includes an opening that is filled by another member when the semiconductor package 10 is completed. Through the opening 45, at least a part of the conductive pad 21 is exposed. The opening 45 is an example of an “exposing portion.” Note that “exposed” referred to herein means that something is exposed to the outside of a member in which an opening is formed. That is, when it is described that “at least a part of the conductive pad 21 is exposed through the opening 45,” this means that at least a part of the conductive pad 21 is exposed, through the opening 45, to the outside of the insulating layer 40 in which the opening 45 is formed. The opening 45 is formed by a part of the insulating layer 40 on the conductive pad 21 being removed by etching (e.g., photolithography). As will be described below, the conductive pad 21 and the metal plating layer 50 are electrically connected through the first via 45 that is in the opening 45. A thickness of the insulating layer 40 is not particularly limited and is preferably, for example, 1 μm or more and 10 μm or less.

Next, the molecular bonding layer 210 will be described.

The molecular bonding layer 210 is formed on at least a surface of the insulating layer 40. The molecular bonding layer 210 has a function of bonding the insulating layer 40 and the metal plating layer 50. The molecular bonding layer 210 is formed by, for example, substantially the same molecular bonding agent as the molecular bonding layer 60 described in the first embodiment. That is, an example of the molecular bonding layer 210 is formed of a compound such as a triazine derivative and includes a triazine dithiol residue. An example of the molecular bonding layer 210 includes the molecular systems 60r (refer to FIG. 3).

As shown in FIG. 7, the molecular bonding layer 210 includes a first portion 210a, a second portion 210b, and a third portion 210c.

The first portion 210a is formed, for example, on a surface 40a of the insulating layer 40 outside the opening 45. The first portion 210a is formed between the surface 40a of the insulating layer 40 and the metal plating layer 50 (e.g., the conductive line 51 included in the metal plating layer 50) and bonds the surface 40a of the insulating layer 40 and the metal plating layer 50 (e.g., the conductive line 51 included in the metal plating layer 50). For example, at least a part of the first portion 210a of the molecular bonding layer 210 is chemically bonded (e.g., covalently bonded) to the insulating material 40m included in the insulating layer 40. In addition, at least a part of the first portion 210a of the molecular bonding layer 210 is chemically bonded (e.g., covalently bonded) to the conductive material (hereinafter referred to as a “first metal” in some cases) 50m included in the metal plating layer 50. For example, the first portion 210a includes the molecular system 60r that is chemically bonded (e.g., covalently bonded) to both the insulating material 40m of the insulating layer 40 and the first metal 50m of the metal plating layer 50. In other words, one molecule of the molecular bonding agent (e.g., the molecular system 60r) included in the first portion 210a is chemically bonded (e.g., covalently bonded) to both the insulating material 40m of the insulating layer 40 and the first metal 50m of the metal plating layer 50. That is, the insulating layer 40 and the metal plating layer 50 are bonded via a chemical bond (e.g., a covalent bond) of the molecular bonding layer 210. As a result, the insulating layer 40 and the metal plating layer 50 are firmly adhered together.

The second portion 210b is formed on an inner surface 45a (e.g., an inner circumferential surface) of the opening 45. The second portion 210b is formed between the inner surface 45a of the opening 45 and the metal plating layer 50 (e.g., the first via 52 included in the metal plating layer 50), and bonds the inner surface 45a of the opening 45 and the metal plating layer 50 (e.g., the first via 52 included in the metal plating layer 50). That is, the second portion 210b is formed between the insulating layer 40 and the first via 52. For example, at least a part of the second portion 210b of the molecular bonding layer 210 is chemically bonded (e.g., covalently bonded) to the insulating material 40m included in the insulating layer 40. At least a part of the second portion 210b of the molecular bonding layer 210 is chemically bonded (e.g., covalently bonded) to the first metal 50m included in the metal plating layer 50. For example, the second portion 210b includes the molecular system 60r that is chemically bonded (e.g., covalently bonded) to both the insulating material 40m of the insulating layer 40 and the first metal 50m of the metal plating layer 50. In other words, one molecule of the molecular bonding agent (e.g., the molecular system 60r) included in the second portion 210b is chemically bonded (e.g., covalently bonded) to both the insulating material 40m of the insulating layer 40 and the first metal 50m of the metal plating layer 50.

The third portion 210c is formed on a surface 21a of the conductive pad 21 that is exposed through the opening 45. The third portion 210c is formed between the surface 21a of the conductive pad 21 and the metal plating layer 50 (e.g., the first via 52 included in the metal plating layer 50) and bonds the surface 21a of the conductive pad 21 and the metal plating layer 50 (e.g., the first via 52 included in the metal plating layer 50). For example, at least a part of the third portion 210c of the molecular bonding layer 210 is chemically bonded (e.g., covalently bonded) to the metal 21m (hereinafter referred to as a “second metal” in some cases) included in the conductive pad 21. At least a part of the third portion 210c of the molecular bonding layer 210 is chemically bonded (e.g., covalently bonded) to the first metal 50m included in the metal plating layer 50. The molecular system 60r chemically bonded (e.g., covalently bonded) to the second metal 21m and the molecular system 60r chemically bonded (e.g., covalently bonded) to the first metal 50m may be the same or different from each other. When one molecule of the molecular system 60r is chemically bonded (e.g., covalently bonded) to both the second metal 21m and the first metal 50m, adhesiveness between the conductive pad 21 and the metal plating layer 50 is further increased. When the molecular bonding layer 210 is formed on both the surface 40a of the insulating layer 40 and the surface 21a of the conductive pad 21 as in this embodiment, the semiconductor chip 20 and the metal plating layer 50 are adhered together more firmly.

For example, the molecular systems 60r of the molecular bonding layer 210 are not, for example, completely uniformly dispersed. The first via 52 of the metal plating layer 50 is in contact with the conductive pad 21 of the semiconductor chip 20 at positions (i.e., regions in which the molecular system 60r is not present) between the plurality of molecular systems 60r. As a result, the first via 52 of the metal plating layer 50 is physically and electrically connected to the conductive pad 21 of the semiconductor chip 20.

For example, at least a part of the first portion 210a, the second portion 210b, and the third portion 210c are integrally formed with each other (i.e., formed in a series with each other). The metal plating layer 50 is chemically bonded to the first portion 210a, the second portion 210b, and the third portion 210c of the molecular bonding layer 210.

A thickness of the molecular bonding layer 210 is preferably 0.5 nm or more and 20 nm or less and more preferably 1 nm or more and 10 nm or less. If the thickness of the molecular bonding layer 210 is the lower limit value or more, it is possible to further increase adhesiveness between the insulating layer 40 and the metal plating layer 50. If the thickness of the molecular bonding layer 210 is the upper limit value or less, an electrical connection between the conductive pad 21 and the metal plating layer 50 can be easily ensured.

At least a part of the molecular bonding layer 210 formed on the surface of the insulating layer 40 has preferably a monomolecular film form. For example, 30 area % or more and 100 area % or less of the molecular bonding layer 210 has preferably a monomolecular film form. More preferably, the entire molecular bonding layer 210 has a monomolecular film form. In a region that is formed in a monomolecular film form in the molecular bonding layer 210, one molecule of the molecular bonding agent is covalently bonded to both the first metal 50m and the insulating material 40m. As a result, adhesiveness between the metal plating layer 50 and the insulating layer 40 is further increased. In addition, an increase in the thickness of the semiconductor package 10 due to the molecular bonding layer 210 is suppressed.

At least a part of the molecular bonding layer 210 formed on the surface 21a of the conductive pad 21 exposed through the opening 45 has preferably a monomolecular film form. For example, 30 area % or more and 100 area % or less of the molecular bonding layer 210 has preferably a monomolecular film (molecular monolayer) form. More preferably, the entire molecular bonding layer 210 has a monomolecular film form. In a region that is formed in a monomolecular film form in the molecular bonding layer 210, one molecule of the molecular bonding agent is covalently bonded to both the first metal 50m and the second metal 21m. As a result, adhesiveness between the conductive pad 21 and the metal plating layer 50 is further increased. In addition, an electrical connection between the conductive pad 21 and the metal plating layer 50 is ensured. In addition, an increase in the thickness of the semiconductor package 10 due to the molecular bonding layer 210 is suppressed.

A coverage ratio of the molecular bonding layer 210 with respect to an area of the insulating layer 40 may be the same as or different from a coverage ratio of the molecular bonding agent with respect to an area of the surface 21a of the conductive pad 21. However, in consideration of adhesiveness between the area of the insulating layer 40 and the metal plating layer 50, a coverage ratio of the molecular bonding agent with respect to the area of the insulating layer 40 is preferably greater than a coverage ratio of the molecular bonding agent with respect to the area of the surface 21a of the conductive pad 21. For example, the coverage ratio of the molecular bonding agent with respect to the area of the insulating layer 40 is preferably 20 area % or more, more preferably 30 area % or more, and most preferably 50 area % or more. If the coverage ratio of the molecular bonding agent with respect to the area of the insulating layer 40 is the lower limit value or more, adhesiveness between the insulating layer 40 and the metal plating layer 50 can be further increased. Since a higher coverage ratio of the molecular bonding layer 210 with respect to the area of the insulating layer 40 is preferable, the upper limit value thereof is not particularly limited. As the upper limit value of the coverage ratio, for example, 70 area % or 80 area % are exemplary examples.

The coverage ratio of the molecular bonding agent with respect to the area of the surface 21a of the conductive pad 21 is preferably 20 area % or more and 80 area % or less, more preferably 30 area % or more and 70 area % or less, and most preferably 40 area % or more and 60 area % or less. If the coverage ratio of the molecular bonding agent with respect to the area of the surface 21a of the conductive pad 21 is the lower limit value or more, adhesiveness between the conductive pad 21 and the metal plating layer 50 can be further increased. In addition, if the coverage ratio of the molecular bonding agent with respect to the area of the surface 21a of the conductive pad 21 is the upper limit value or less, an electrical connection between the conductive pad 21 and the metal plating layer 50 can be ensured.

Other configurations and functions of the molecular bonding layer 210 are substantially the same as the configurations and functions of the molecular bonding layer 60 according to the first embodiment. That is, other descriptions related to the molecular bonding layer 210 would be understood as replacement of “the molecular bonding layer 60” with “the molecular bonding layer 210,” “the upper insulating layer 70” with “the lower insulating layer 40” or “the conductive pad 21”, and “the insulating material 70m” with “the insulating material 40m” or “the metal 21m” in the descriptions related to the molecular bonding layer 60 of the first embodiment. For example, an adhesion strength between the insulating layer 40 and the metal plating layer 50 may be substantially the same as or different from the adhesion strength between the redistribution layer 50 and the upper insulating layer 70 in the first embodiment.

Next, the metal plating layer 50 will be described.

The metal plating layer 50 is a member having a function of a conductive line (i.e., an interconnect, or wiring pattern) through which electrical signals flow in the semiconductor package 10 and is, for example, a redistribution layer. The metal plating layer 50 is bonded to the surface of the insulating layer 40 by the molecular bonding layer 210. The metal plating layer 50 is physically and electrically connected to the conductive pad 21 in the opening 45 of the insulating layer 40. Also, as described above, the third portion 210c of the molecular bonding layer 210 may be formed between the metal plating layer 50 and the conductive pad 21. Thereby, the metal plating layer 50 and the conductive pad 21 are adhered together more firmly.

In addition, from a certain point of view, the metal plating layer 50 is bonded to the first portion 210a, the second portion 210b, and the third portion 210c of the molecular bonding layer 210. For example, the metal plating layer 50 includes the conductive line 51 and the first via 52. The conductive line 51 is formed on the surface 40a of the insulating layer 40 outside the opening 45 and is bonded to the first portion 210a of the molecular bonding layer 210. The first via 52 is formed in the opening 45 and is bonded to the second portion 210b and the third portion 210c of the molecular bonding layer 210.

As shown in FIG. 7, the metal plating layer 50 according to the present embodiment includes a first metal plating layer 55 and a second metal plating layer 56. The first metal plating layer 55 and the second metal plating layer 56 are laminated in a thickness direction of the metal plating layer 50.

The first metal plating layer 55 is a seed layer including a seed metal 55m serving as a growth starting point of the redistribution layer 50 including the second metal plating layer 56. The seed metal 55m is metal (i.e., a metal material) forming the first metal plating layer 55. Examples of the seed metal 55m of the present embodiment include a metal such as palladium. A thickness of the first metal plating layer 55 is not particularly limited and is preferably, for example, 0.05 μm or more and 2 μm or less, in consideration of a function as the growth starting point. The first metal plating layer 55 can be formed by a metal plating treatment on a surface of the molecular bonding layer 210 using the seed metal 55m. In the present embodiment, the first metal plating layer 55 is bonded to the insulating layer 40 by the molecular bonding layer 210. That is, in the present embodiment, the seed metal 55m is an example of the first metal 50m that is chemically bonded (e.g., covalently bonded) to the molecular bonding layer 210.

The second metal plating layer 56 is a main body of the redistribution layer 50 and includes a redistribution metal 56m. The redistribution metal 56m is a metal (i.e., a metal material) forming the second metal plating layer 56. The redistribution metal 56m is metal such as copper, nickel and alloys thereof. The redistribution metal 56m may be the same as or different from the second metal 21m. A thickness of the second metal plating layer 56 is not particularly limited and is preferably, for example, 1 μm or more and 10 μm or less. If the thickness of the second metal plating layer 56 is the lower limit value or more, it is possible to suppress disconnection of a conductive line for an electrical signal. If the thickness of the second metal plating layer 56 is the upper limit value or less, it is possible to suppress an increase in the thickness of the semiconductor package 10 due to the molecular bonding layer 210. The first metal 50m includes the seed metal 55m or both the seed metal 55m and the redistribution metal 56m.

Next, an example of a method of manufacturing the semiconductor package 10 according to the present embodiment will be described. Also, the following processes are, for example, processes corresponding to (c) to (0 in FIG. 4A.

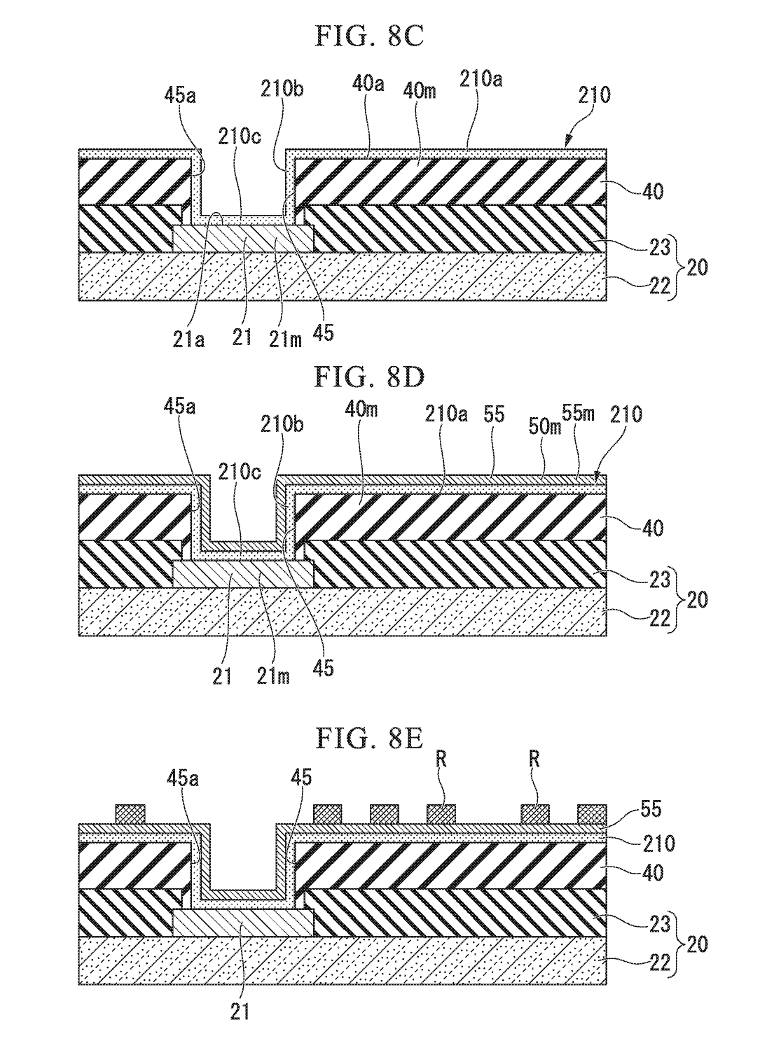

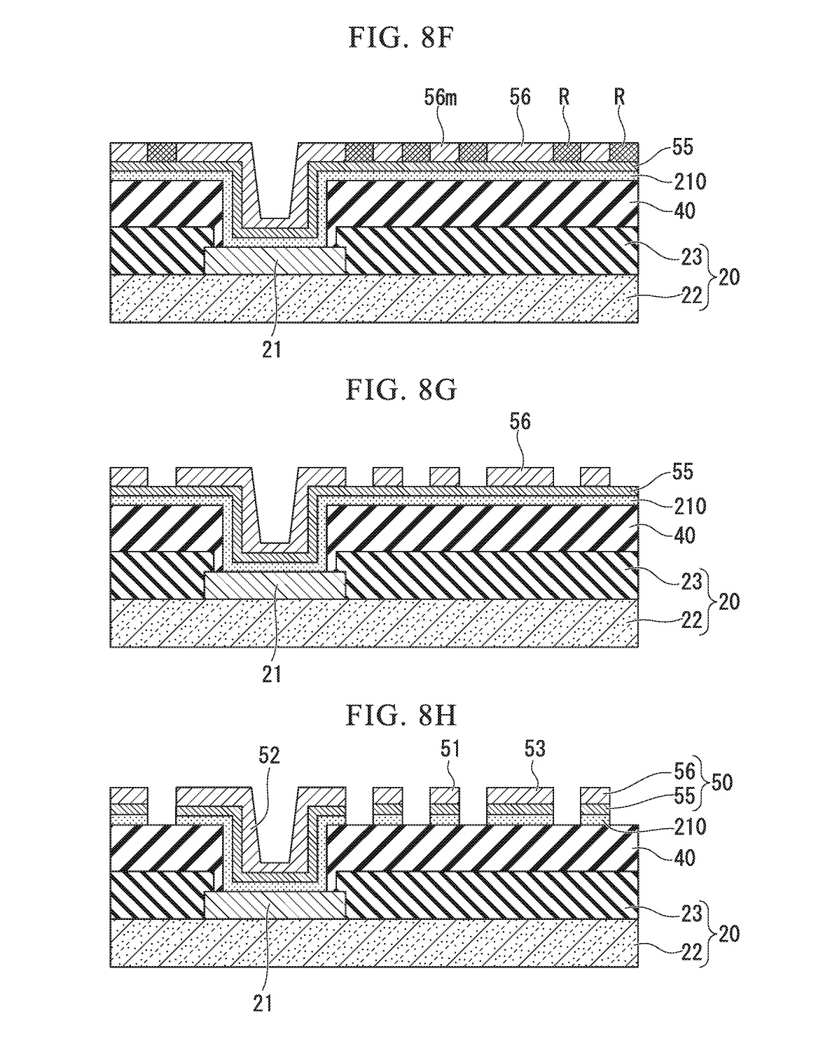

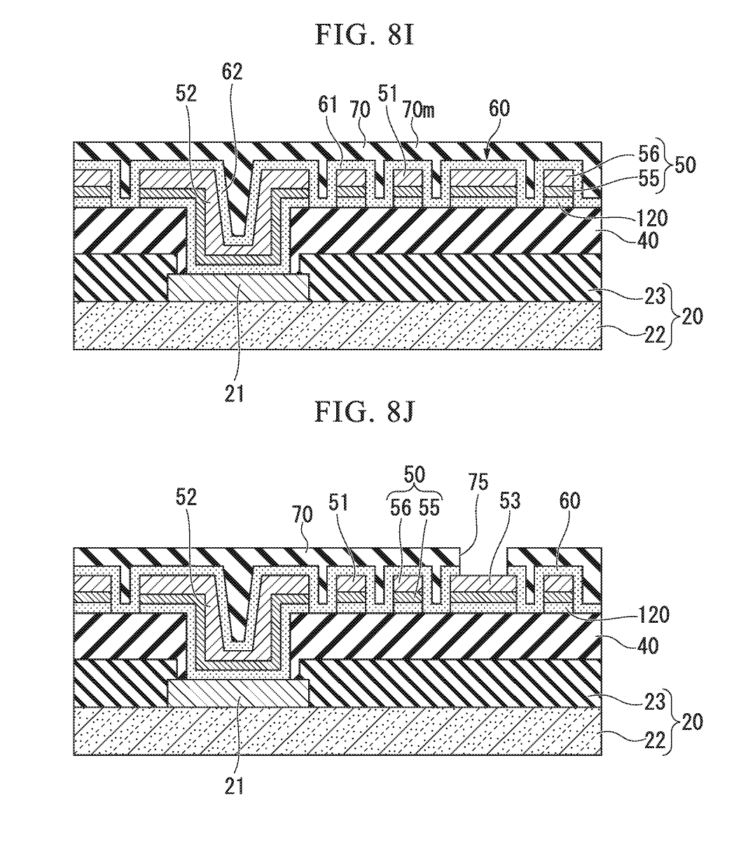

First, the semiconductor chip 20 including the semiconductor substrate 22, the conductive pads 21, and the insulating film 23 is prepared (FIG. 8A). Next, the insulating layer 40 is formed by the insulating material 40m being supplied to the surface of the semiconductor chip 20. Next, the opening 45 (i.e., a through hole) is formed in the insulating layer 40 (FIG. 8B). The opening 45 is formed in a region corresponding to the conductive pad 21 of the semiconductor chip 20 and penetrates through the insulating layer 40. The opening 45 is formed by etching, for example, the insulating layer 40.

Next, the molecular bonding layer 210 including the first portion 210a, the second portion 210b, and the third portion 210c is formed by at least covering the surface 40a of the insulating layer 40 outside the opening 45, the inner surface 45a of the opening 45, and the surface 21a of the conductive pad 21 exposed through the opening 45 with the molecular bonding agent (i.e., by at least applying the molecular bonding agent to the surface 40a of the insulating layer 40 outside the opening 45, the inner surface 45a of the opening 45, and the surface 21a of the conductive pad 21 exposed through the opening 45) (FIG. 8C). For example, while the insulating layer 40 to which the molecular bonding agent solution is applied is left, chemical bonding (e.g., covalent bonding) between the insulating material 40m of the insulating layer 40 and the molecular bonding agent is promoted. Further, an operation of applying energy (e.g., heat or light (e.g., ultraviolet rays)) to a molecular bonding layer 120 may be performed. The heating temperature and the heating time are appropriately determined according to an applied amount of the molecular bonding agent solution. In addition, the wavelength of the ultraviolet rays to be emitted is preferably 250 nm or less and an emission time is appropriately determined according to the applied amount of the molecular bonding agent solution. Then, the insulating layer 40 is cleaned using a cleaning solution and dried. Therefore, the molecular bonding layer 210 chemically bonded (e.g., covalently bonded) to the insulating material 40m of the insulating layer 40 and the second metal 21m of the conductive pad 21 is formed. Also, details of a method of forming the molecular bonding layer 210 are substantially the same as details of the method of forming the molecular bonding layer 60 described in the first embodiment. For example, the molecular bonding agent is supplied as the form of a molecular bonding agent solution described above in the first embodiment.

Chemical bonding (e.g., covalent bonding) of the molecular bonding agent may be performed without applying energy such as heat or light. Alternatively, chemical bonding (e.g., covalent bonding) of the molecular bonding agent may be performed by applying energy such as heat or light.

The thickness of the molecular bonding layer 210 can be adjusted according to conditions such as a concentration and an applied amount of the molecular bonding agent solution, a cleaning time and the number of cleanings. In addition, a coverage ratio of the molecular bonding layer 210 with respect to the area of the surface 21a of the conductive pad 21 can be adjusted according to conditions such as the concentration and the applied amount of the molecular bonding agent solution, the cleaning time and the number of cleanings.

Next, a metal plating treatment is performed on surfaces of the first portion 210a, the second portion 210b, and the third portion 210c of the molecular bonding layer 210. For example, a first metal plating treatment using the above-described seed metal 55m is performed on the surface of the molecular bonding layer 210 (e.g., surfaces of the first portion 210a, the second portion 210b, and the third portion 210c). As a result, the first metal plating layer 55 (e.g., a seed layer) including the seed metal 55m serving as a growth starting point of the metal plating layer (e.g., the redistribution layer) 50 is formed on the molecular bonding layer 210 (FIG. 8D).

For example, while the first metal plating layer 55 formed on the molecular bonding layer 210 is left, chemical bonding (e.g., covalent bonding) between the first metal 50m (e.g., the seed metal 55m) included in the first metal plating layer 55 and the molecular bonding layer 210 is promoted. Further, an operation of applying energy (e.g., heat or light (e.g., ultraviolet rays)) to the molecular bonding layer 120 may be performed and chemical bonding (e.g., covalent bonding) between the first metal 50m (e.g., the seed metal 55m) included in the first metal plating layer 55 and the molecular bonding layer 210 may be promoted.

Next, a resist film R for forming a wiring pattern (i.e., conductive lines 51) is formed at a specific location on the first metal plating layer 55 by, for example, photolithography (FIG. 8E). Then, a second metal plating treatment using the above-described redistribution metal 56m is performed on a surface of the first metal plating layer 55. As a result, a film made of the redistribution metal 56m grows using the seed metal 55m of the first metal plating layer 55 as a growth starting point and the second metal plating layer 56 is formed (FIG. 8F).

The first metal plating treatment for forming the seed layer may be either an electrolytic plating treatment or an electroless plating treatment. The first metal plating treatment is, for example, an electroless plating treatment. The “electroless plating treatment” referred to herein is not limited to a spray plating treatment but may include various other known electroless plating treatments. When the electroless plating is used, the first metal plating layer 55 having a fine and uniform shape can be formed. In addition, it is possible to minimize equipment costs and maintenance costs for the metal plating treatment.

The second metal plating treatment for forming a main body of the redistribution layer may be either electrolytic plating or electroless plating. The second metal plating treatment is, for example, an electrolytic plating treatment. By electrolytic plating being used, the second metal plating layer 56 having a thickness of 1 μm or more and preferably 2 μm or more can be formed.

When the metal plating treatment described above is performed, the metal plating layer 50 that is electrically connected to the conductive pad 21 in the opening 45 of the insulating layer 40 can be formed.

After the metal plating layer 50 is formed, a part of the second metal plating layer 56 formed in the opening 45 may be removed by photolithography and the recess 52a of the first via 52 may be formed. In addition, the resist film R formed on the first metal plating layer 55 is removed by cleaning (refer to FIG. 8G). Then, in the first metal plating layer 55, a portion in which the second metal plating layer 56 is not formed is removed by etching (FIG. 8H). When the first metal plating layer 55 is removed, a part of the molecular bonding layer 210 may be removed as well.

According to the method described, the semiconductor package 10 of this embodiment is formed.

In the present embodiment, the semiconductor package 10 may include two or more each of insulating layers and metal plating layers. In that case, for example, the molecular bonding layer 60 is newly formed on a surface of the metal plating layer 50 and an exposed surface of the insulating layer 40. Then, the second insulating layer 70 is formed on the surface of the metal plating layer 50 and the exposed surface of the insulating layer 40 via the molecular bonding layer 60 (FIG. 8I). The opening 75 is formed by a certain location on the second insulating layer 70 formed on the metal plating layer 50 being etched (FIG. 8J). Then, a second metal plating layer (e.g., the second redistribution layer 80) is formed on the metal plating layer 50 and the second insulating layer 70 via the molecular bonding layer 220.

By carrying out the above-described processing, the insulating layers and the metal plating layers can be laminated via the molecular bonding layer.

Also, the molecular bonding agent forming the molecular bonding layer 210 may be the same as or different from the molecular bonding agent forming the molecular bonding layers 60 and 220.

The semiconductor package 10 of the second embodiment includes the semiconductor chip 20, the molecular bonding layer 210, and the metal plating layer 50. The molecular bonding layer 210 is bonded to the insulating layer 40 and the metal plating layer 50 via a chemical bond (i.e., a covalent bond). As a result, adhesiveness between the insulating layer 40 and the metal plating layer 50 can be increased. In addition, by forming the molecular bonding layer 210 between the conductive pad 21 of the semiconductor chip 20 and the metal plating layer 50, adhesiveness between the semiconductor chip 20 and the metal plating layer 50 can be further increased and an electrical connection between the conductive pad 21 of the semiconductor chip 20 and the metal plating layer 50 can be appropriately ensured.

In addition, according to the method of manufacturing the semiconductor package 10 according to the embodiment, the first metal plating layer 55 (e.g., the seed layer) can be formed using electroless plating without using a vapor deposition method such as sputtering. Since the surface of the insulating layer 40 of the base can be metallized without coarsening, the seed layer having a fine pattern can be formed. In addition, it is possible to reduce production costs and increase the efficiency of production.

### Third Embodiment

A configuration of the semiconductor package 10 according to a third embodiment is substantially the same as the configuration of the semiconductor package 10 according to the second embodiment. The third embodiment is different from the second embodiment in that at least a part of the metal plating layer 50 is formed by a spray plating treatment. Configurations not described below are the same as those in the second embodiment.

For example, in the third embodiment, the first metal plating layer 55 is formed by a spray plating treatment. In the spray plating treatment, a metal ion solution including the first metal 50m (e.g., the seed metal 55m) and a reducing agent solution are sprayed. The spray plating treatment is, for example, autocatalytic electroless plating.

For example, the first metal plating treatment using the first metal 50m (e.g., the seed metal 55m) is performed on the surface of the molecular bonding layer 210. As a result, the first metal plating layer 55 is formed on the molecular bonding layer 210. The first metal plating layer 55 is a seed layer that includes a growth starting point of the metal plating layer 50 including the second metal plating layer 56 which will be formed later. In the present embodiment, the first metal plating treatment is a spray plating treatment and a metal ion solution and a reducing agent solution are sprayed onto the surface of the molecular bonding layer 210.

The metal ion solution is a solution that includes metal ions derived from the first metal 50m (e.g., the seed metal 55m). The first metal 50m (e.g., the seed metal 55m) of the present embodiment is an autocatalytic metal, for example, palladium, copper, silver, nickel, and lead. Furthermore, the first metal 50m (e.g., the seed metal 55m) is at least one type selected from the group consisting of copper, silver and nickel. Examples of such metal ions include copper ions, silver ions and nickel ions. As a solvent that dissolves metal ions, polar solvents can be used. Among them, water is preferable. The concentration of the metal ion solution is not particularly limited and a known concentration can be applied.

The temperature of the metal ion solution is not particularly limited as long as it is within a practical range, and is preferably, for example, 20° C. or more and 40° C. or less. If the temperature of the metal ion solution is the lower limit value or more, a metal ion solution in which metal ions are favorably dissolved in a solvent can be obtained. If the concentration of the metal ion solution is upper limit value or less, it is possible to effectively suppress evaporation of the solvent.

The reducing agent solution is a solution including a reducing agent that reduces metal ions to precipitate a metal. As the reducing agent, a known compound corresponding to metal ions to be used can be used. When copper ions or silver ions are used as metal ions, formaldehyde is preferably used as the reducing agent because an autocatalytic reaction occurs. In addition, when nickel ions are used as metal ions, a phosphinate or tetrahydroborate is preferably used as the reducing agent because an autocatalytic reaction occurs. As a solvent that dissolves a reducing agent, polar solvents can be used. Among them, water is preferable.

A concentration of the reducing agent solution is not particularly limited and a known concentration can be applied.

A temperature of the reducing agent solution is not particularly limited as long as it is within a practical range and is preferably, for example, 20° C. or more and 40° C. or less. If a temperature of the reducing agent solution is the lower limit value or more, a reducing agent solution in which the reducing agent is favorably dissolved in a solvent can be obtained. If a concentration of the reducing agent solution is the upper limit value or less, it is possible to effectively suppress evaporation of the solvent.

The autocatalytic reaction refers to a reaction in which a metal produced when metal ions are reduced by a reducing agent serves as a catalyst in oxidation of the reducing agent. In the present embodiment, autocatalytic electroless plating is preferably used as the metal plating treatment because it further increases the efficiency of production.

A buffering agent such as acetic acid, a complexing agent such as tartaric acid, a stabilizing agent such as a cyano compound, or the like may be added to at least one of the metal ion solution and the reducing agent solution as an additive. Examples of the buffering agent include a mixture of acetic acid and acetate. Examples of the complexing agent include tartaric acid, citric acid, malic acid, and pyrophosphoric acid. Examples of the stabilizing agent include a cyano compound and a bipyridine compound.

By adding such an additive, long-term storability of the metal ion solution or the reducing agent solution is improved. In addition, the metal plating layer 50 can be reliably formed.

A method of spraying the metal ion solution and the reducing agent solution is not particularly limited. For example, two spray devices are used and the metal ion solution and the reducing agent solution are sprayed on the same location on the surface of the molecular bonding layer 210 in two directions. When such a spray method is used, the metal ion solution and the reducing agent solution are simultaneously sprayed and thus a metal plating treatment can be performed on the molecular bonding layer 210.

The second metal plating treatment and processes thereafter in the present embodiment are the same as those in the second embodiment. Also, in the present embodiment, the redistribution metal 56m forming the second metal plating layer 56 may be the same as the seed metal 55m forming the first metal plating layer 55. The second metal plating layer 56 is formed through, for example, an electroless plating treatment different from a spray plating treatment or an electrolytic plating treatment. For example, the second metal plating layer 56 is formed by an electrolytic plating treatment.

According to the method of producing a semiconductor device of the present embodiment, electroless plating is used to form the first metal plating layer 55. For that reason, a fine wiring pattern can be formed without coarsening the surfaces of the molecular bonding layer 210 and the semiconductor chip 20 serving as the base.

In addition, according to the method of producing the semiconductor package 10 according to the embodiment, since the reducing agent solution and the metal ion solution are sprayed for the metal plating treatment, the metal plating layer 50 can be formed without using a seed metal such as palladium. Since a seed metal such as palladium is expensive generally, it is possible to reduce production costs of the method of manufacturing the semiconductor package 10 according to the embodiment. In addition, silver ions which are one of preferable metal ions have excellent removability compared to palladium. Therefore, by using a silver ion solution, it is possible to further increase the efficiency of production of the semiconductor package 10.

In addition, according to the method of producing the semiconductor package 10 of the present embodiment, the insulating layer 40 and the metal plating layer 50 are bonded by the molecular bonding layer 210. For that reason, adhesiveness inside the semiconductor package 10 is good. In addition, there is no need to perform a zincate treatment on the conductive pad 21 made of, for example, aluminum or an aluminum alloy, to increase adhesiveness.

### Fourth Embodiment

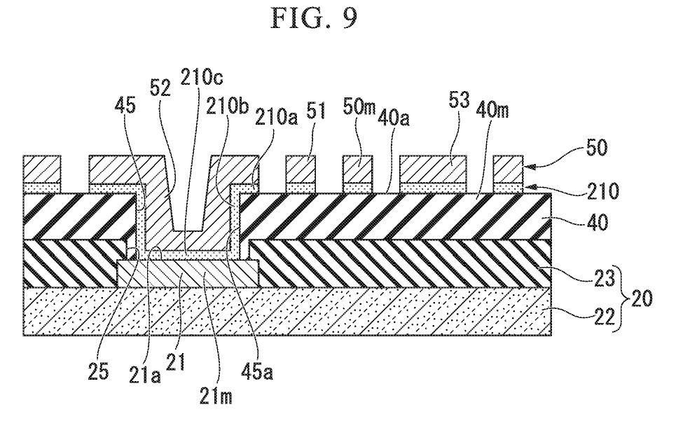

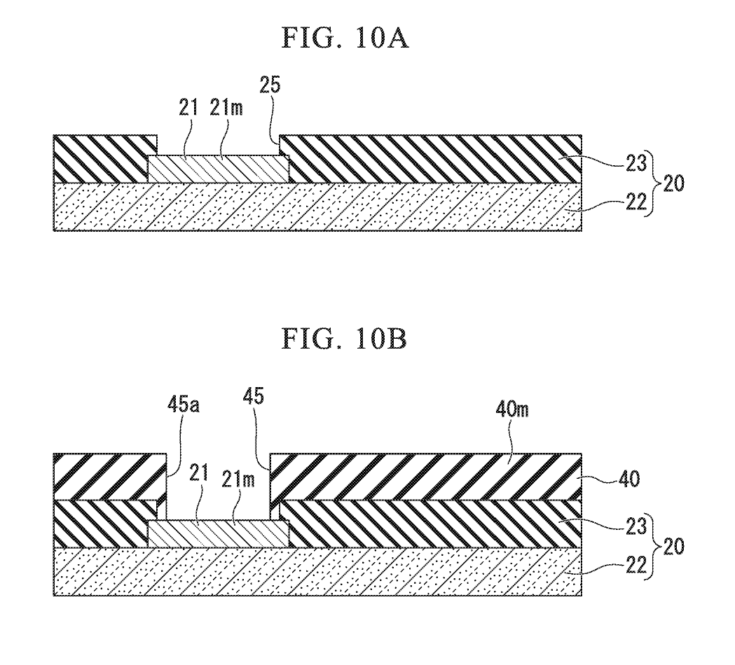

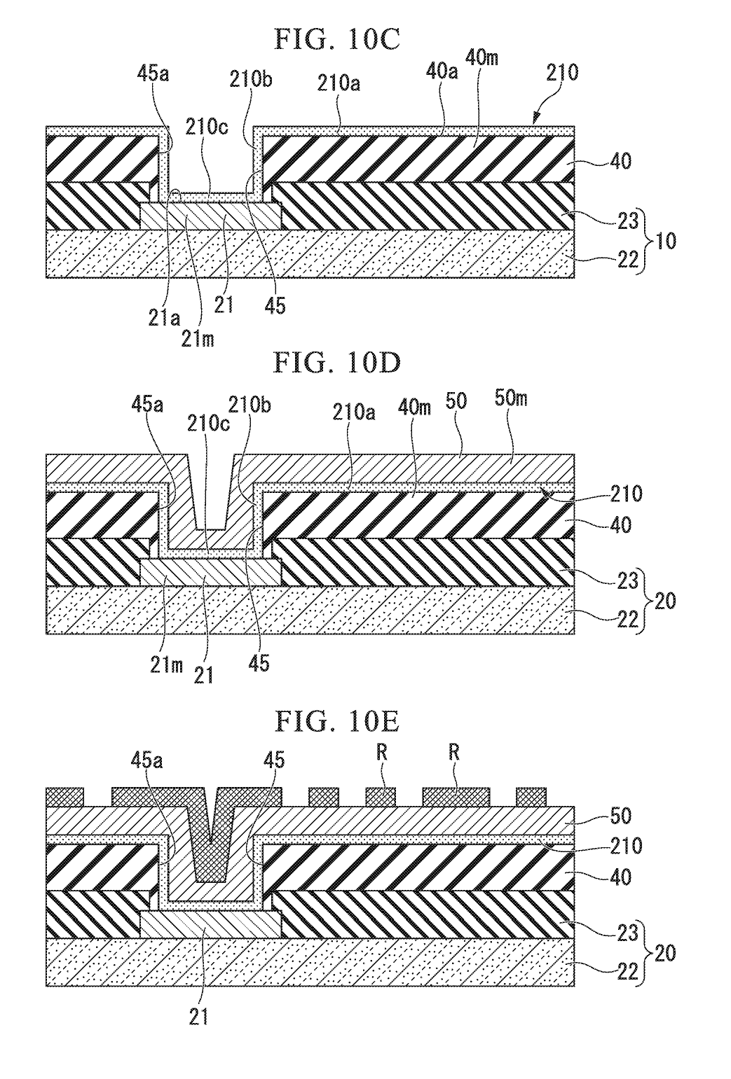

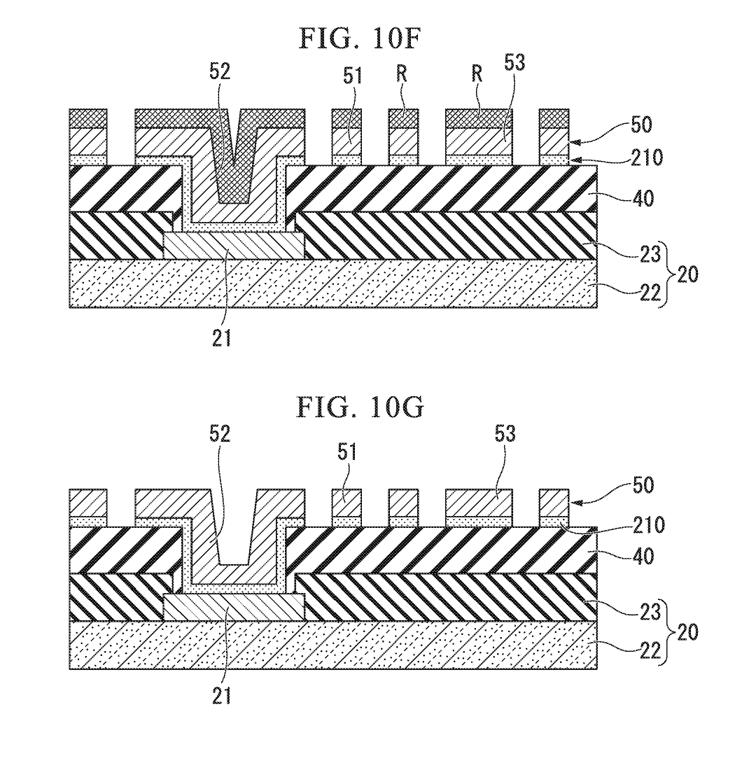

A fourth embodiment will be described with reference to FIG. 9 to FIG. 10G. The fourth embodiment is different from the third embodiment in that the entire metal plating layer 50 is formed by a spray plating treatment. Configurations not described below are the same as those in the third embodiment.

FIG. 9 is a cross-sectional view of the semiconductor package 10 according to the fourth embodiment.

As shown in FIG. 9, in the semiconductor package 10 according to the fourth embodiment, one metal plating layer 50 is formed in place of the first metal plating layer 55 and the second metal plating layer 56. In other words, the metal plating layer 50 of the present embodiment does not include a seed layer.

Next, an example of a method of producing the semiconductor package 10 of the present embodiment will be described. The following processes are, for example, processes corresponding to (c) to (0 in FIG. 4A.

First, the semiconductor chip 20 including the semiconductor substrate 22, the conductive pads 21, and the insulating film 23 is prepared (FIG. 10A). Next, the insulating layer 40 is formed by forming the insulating material 40m on the surface of the semiconductor chip 20. Next, the opening 45 (i.e., a through hole) is formed in the insulating layer 40 (FIG. 10B). The opening 45 is formed in a region corresponding to the conductive pad 21 of the semiconductor chip 20 and penetrates through the insulating layer 40. The opening 45 is formed by etching, for example, the insulating layer 40.

Next, the molecular bonding layer 210 is formed by covering the surface 40a of the insulating layer 40 different from the opening 45, the inner surface 45a of the opening 45, and the surface 21a of the conductive pad 21 exposed through the opening 45 with the molecular bonding agent (FIG. 10C). Also, the processes up to this point are the same as those in the second embodiment.

In the present embodiment, a metal plating treatment is performed on the surface of the molecular bonding layer 210. The metal plating treatment of the present embodiment, similarly to the first metal plating treatment of the third embodiment, is a spray plating treatment. That is, a metal ion solution including the first metal 50m and a reducing agent solution are sprayed. In the spray plating treatment, a deposition rate of the metal plating layer is higher than those in other types of electroless plating. For that reason, the spray plating treatment can be performed on the entire metal plating layer 50. In addition, if the metal plating layer 50 is formed by the spray plating treatment, since the molecular bonding layer 210 is also formed between the metal plating layer 50 and the insulating layer 40, the metal plating layer 50 is reliably formed. In addition, compared to electrolytic plating, it is possible to increase efficiency of production of the semiconductor package 10.

Next, the resist film R is formed to cover the metal plating layer 50 (FIG. 10E). Next, an unnecessary part of the metal plating layer 50 is removed by etching (FIG. 10F). As a result, the metal plating layer 50 including the conductive line 51 and the first via 52 is formed on the insulating layer 40 (FIG. 10G).

According to at least one of the embodiments described above, it is possible to provide a semiconductor package with increased adhesiveness between a metal plating layer and an insulating layer by a molecular bonding layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor chip covered with a resin layer, the semiconductor chip including an electrode pad at a surface of the semiconductor chip;
a first insulating layer covering the surface of the semiconductor chip and having a via hole at a region corresponding to the electrode pad;
a conductive layer extending along a surface of the electrode pad, a side surface of the via hole, and a surface the first insulating layer to a region beyond a planar region defined by the semiconductor chip;
a second insulating layer on the first insulating layer and covering the conductive layer; and
a molecular bonding layer between the first insulating layer and the second insulating layer and including a first molecular portion covalently bonded to a material of the conductive layer and a material of the second insulating layer.

2. The semiconductor device according to claim 1, wherein
the first molecular portion is on a portion of the conductive portion that is on the surface of the first insulating layer.

3. The semiconductor device according to claim 1, wherein
the first molecular portion is on a portion of the conductive layer that is on the side surface of the via hole.

4. The semiconductor device according to claim 1, wherein
the first molecular portion is formed on a portion of the conductive layer that is on the surface of the electrode pad.

5. The semiconductor device according to claim 1, wherein
the molecular bonding layer further includes a second molecular portion covalently bonded to a material of the first insulating layer and the material of the second insulating layer.

6. The semiconductor device according to claim 1, wherein
the molecular bonding layer includes a triazine dithiol residue.

7. The semiconductor device according to claim 1, wherein
a coverage ratio of the molecular bonding layer on a surface of the conductive layer is greater than 20% and equal to or smaller than 80%.

8. The semiconductor device according to claim 1, wherein
at least a portion of the molecular bonding layer is a monomolecular layer.

9. The semiconductor device according to claim 1, further comprising:
a second conductive layer extending along a surface of the conductive layer, a side surface of a via hole formed in the second insulating layer, and a planar surface of the second insulating layer, wherein
the molecular bonding layer further includes a second molecular portion covalently bonded to the material of the conductive layer and a material of the second conductive layer in the via hole in the second insulating layer.

10. The semiconductor device according to claim 9, further comprising:
a solder ball formed on the second conductive layer.

11. The semiconductor device according to claim 9, further comprising:
a second molecular bonding layer formed between the second conductive layer and the solder ball, and including a molecular portion covalently bonded to the material of the second conductive layer and a material of the solder ball.

12. The semiconductor device according to claim 11, wherein
the second molecular bonding layer includes a triazine dithiol residue.

13. The semiconductor device according to claim 11, wherein
a coverage ratio of the second molecular bonding layer on a surface of the second conductive layer is greater than 20% and equal to or smaller than 80%.

14. A semiconductor device comprising:
a semiconductor chip covered with a resin layer, the semiconductor chip including an electrode pad at a surface of the semiconductor chip;
a first insulating layer covering the surface of the module and having a via hole at a region corresponding to the electrode pad;
a first conductive layer extending along a surface of the electrode pad, a side surface of the via hole, and a planar surface the first insulating layer to a region beyond of a planar region defined by the semiconductor chip;
a second insulating layer formed on the first insulating layer, covering the first conductive layer, and having a via hole therein;
a second conductive layer extending along a surface of the first conductive layer, a side surface of the via hole in the second insulating layer, and a planar surface of the second insulating layer;
a solder ball on the second conductive layer; and
a molecular bonding layer between the second conductive layer and the solder ball, and including a molecular portion covalently bonded to a material of the second conductive layer and a material of the solder ball.

15. The semiconductor device according to claim 14, wherein
the molecular portion is on a portion of the second conductive layer that is on a planar surface of the second insulating layer.

16. The semiconductor device according to claim 14, wherein
the molecular portion is on a portion of the second conductive layer that is on the side surface of the via hole in the second insulating layer.

17. The semiconductor device according to claim 14, wherein
the molecular portion is on a portion of the second conductive layer that is on the surface of the first conductive layer.

18. The semiconductor device according to claim 14, wherein
the molecular bonding layer includes a triazine dithiol residue.

19. The semiconductor device according to claim 14, wherein
a coverage ratio of the molecular bonding layer on a surface of the second conductive layer is greater than 20% and equal to or smaller than 80%.

20. The semiconductor device according to claim 14, wherein
at least a portion of the molecular bonding layer is a monomolecular layer.
